(19) United States
(12) Patent Application Publication
(10) Pub. No.: US 2025/0048781 A1
(43) Pub. Date: Feb. 6, 2025

(54) SEMICONDUCTOR PHOTONICS DEVICE AND METHODS OF FORMATION

(71) Applicant: Taiwan Semiconductor Manufacturing Company, Ltd., Hsinchu (TW)

(72) Inventors: Wen-Shun LO, Hsinchu County (TW); Sheng Kai YEH, Taichung City (TW); Jing-Hwang YANG, Zhubei City (TW); Chi-Yuan SHIH, Hsinchu (TW); Shih-Fen HUANG, Jhubei (TW); YingKit Felix TSUI, Cupertino, CA (US)

(21) Appl. No.: 18/365,678

(22) Filed: Aug. 4, 2023

(51) Int. Cl. H01L 31/024; G02B 6/122; H01L 21/768

(52) U.S. Cl. CPC H01L 31/024; G02B 6/122; H01L 21/76883

(57) ABSTRACT

A modulator heater structure may include a plurality of regions having different thicknesses. For example, a heater ring of the modulator heater structure may have a first thickness. A heater pad of the modulator heater structure, that is configured to provide an electrical current to the heater ring, may have a second thickness that is greater than the first thickness. The lesser thickness of the heater ring of the modulator heater structure provides high electrical resistance in the heater ring, which enables the heater ring to quickly and efficiently generate heat. The greater thickness of the heater pad provides low electrical resistance in the second region, which enables the electrical current to be efficiently provided through the heater pad to the heater ring with reduced heat dissipation in the hear pad due to the lower electrical current dissipation in the heater pad.

### BACKGROUND

A semiconductor device may be configured to use optical signals for high speed and secure data transmission between integrated circuits and/or semiconductor dies of the semiconductor device. An optical signal may be transferred through a waveguide in the semiconductor device. The waveguide enables confinement of the optical signal, which may reduce optical loss and increase propagation efficiency for the optical signal. Data may be encoded into an optical signal by modulating light into optical pulses through an optical modulator. The optical pulses are then transferred to the waveguide for propagation to other regions of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is diagram of an example semiconductor device described herein.

FIGS. 3A and 3B illustrate example implementations of one or more portions of a semiconductor device described herein.

FIGS. 4A-4AA are diagrams of an example implementation of forming a semiconductor device described herein.

FIG. 5 is diagram of an example semiconductor device described herein.

FIGS. 6A-6U are diagrams of an example implementation of forming a semiconductor device described herein.

FIG. 7 is a diagram of example components of a device described herein.

FIG. 8 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a photonic integrated circuit that includes a waveguide and an optical modulator may be included in a dielectric region of a semiconductor device. The dielectric region may be located above a substrate of the semiconductor device. The resonant wavelengths of the optical modulator may be sensitive to variations in processes and operating temperatures. Thus, a modulator heater structure may be included in the dielectric region to stabilize the operating temperature of the optical modulator, thereby stabilizing the operating performance of the optical modulator.

The modulator heater structure may include a heater ring directly above the optical modulator. The heater ring may be configured to receive and to dissipate an electrical current, thereby generating the heat that is used to heat the optical modulator. The heater ring may be coupled with a heater pad of the modulator heater structure. The heater pad may be configured to provide the electrical current to the heater ring (e.g., from one or more back end of line (BEOL) interconnects). Some of the electrical current may also be dissipated in the heater pad, which may reduce the operating efficiency of the modulator heater structure. Dissipated electrical current in the heater pad results in less of the electrical current being provided to the heater ring. Thus, the more electrical current dissipated in the heater pad, the lower the operating efficiency of the modulator heater structure.

In some implementations described herein, a waveguide structure and an optical modulator structure of a semiconductor photonics device are included in a dielectric region above a substrate of the semiconductor photonics device. A modulator heater structure is included above the optical modulator structure to stabilize the operation of the optical modulator structure during operation by heating the optical modulator structure to a stabilized temperature.

The modulator heater structure may include a plurality of regions having different thicknesses. For example, a heater ring of the modulator heater structure, directly above the optical modulator structure, may have a first thickness. A heater pad of the modulator heater structure, that is configured to provide an electrical current to the heater ring, may have a second thickness that is greater than the first thickness. The lesser thickness of the heater ring of the modulator heater structure provides high electrical resistance in the heater ring, which enables the heater ring to quickly and efficiently generate heat that may be provided to stabilize the operating temperature of the optical modulator structure. The greater thickness of the heater pad provides low electrical resistance in the second region, which enables the electrical current to be efficiently provided through the heater pad to the heater ring with reduced heat dissipation in the heater pad due to the lower electrical current dissipation in the heater pad. This enables the modulator heater structure to operate more efficiently, and to consume less electrical current to provide a similar amount of heat to the optical modulator relative to other modulator heater structure configurations.

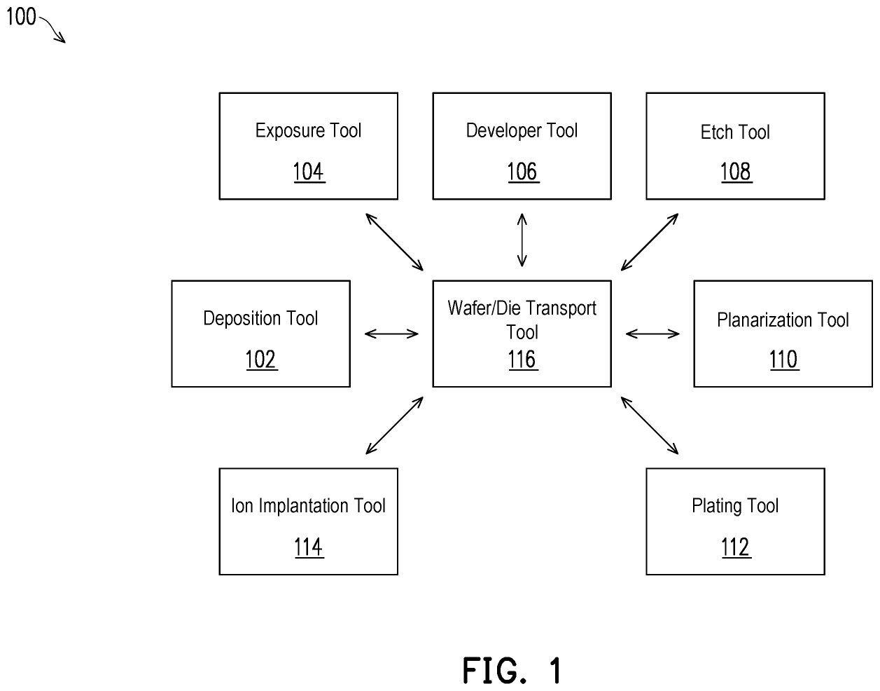

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low-pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of different types of deposition tools 102. “Deposition tool 102,” as used herein, may refer to one or more deposition tools 102, one or more of the same type of deposition tools 102, and/or one or more different types of deposition tools 102, among other examples.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

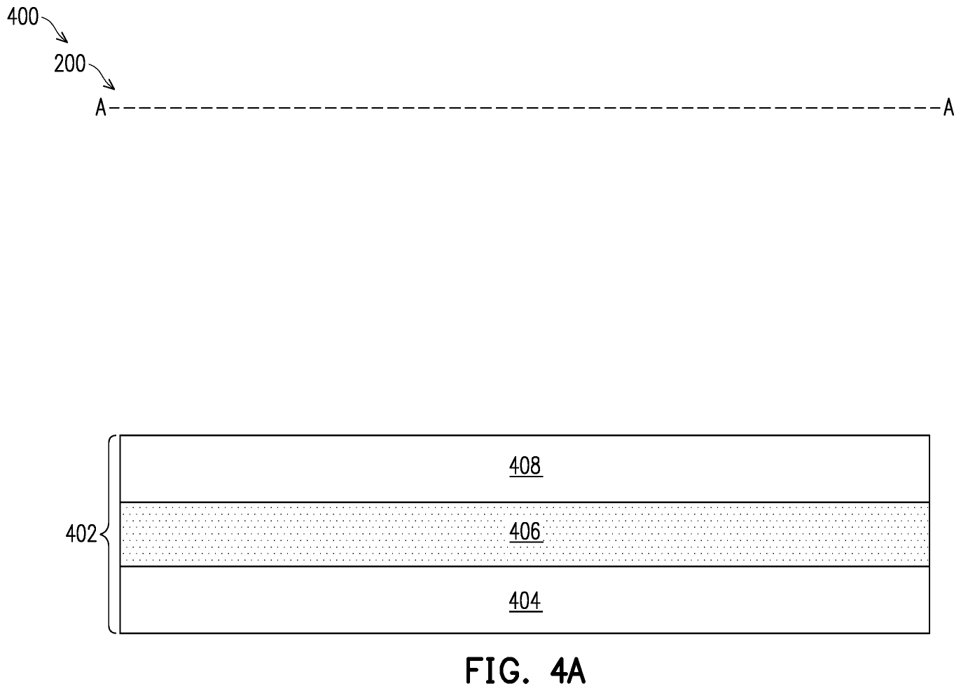

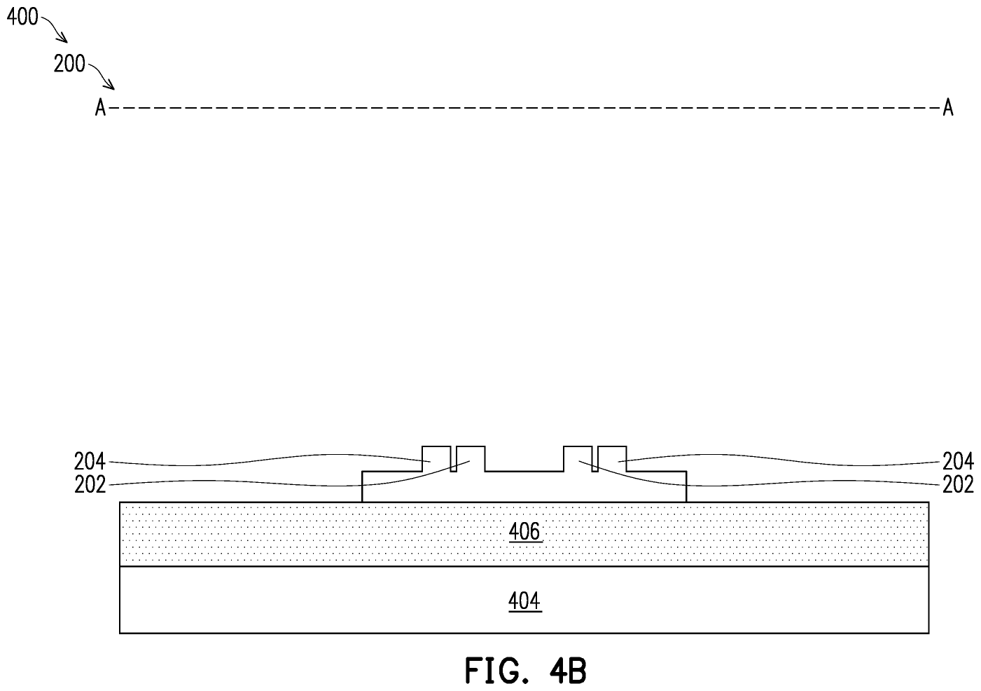

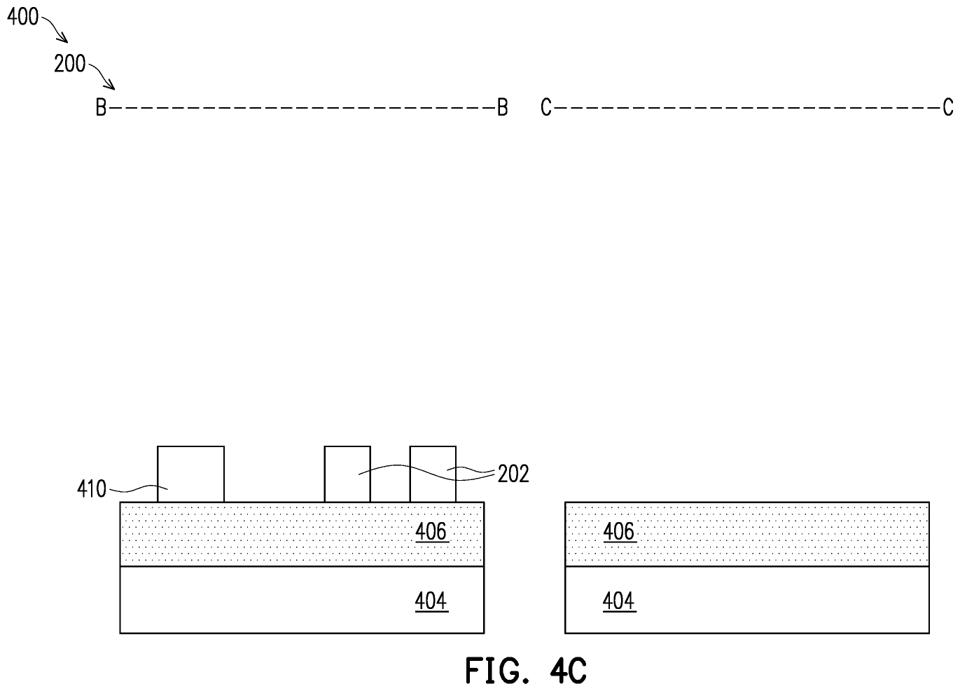

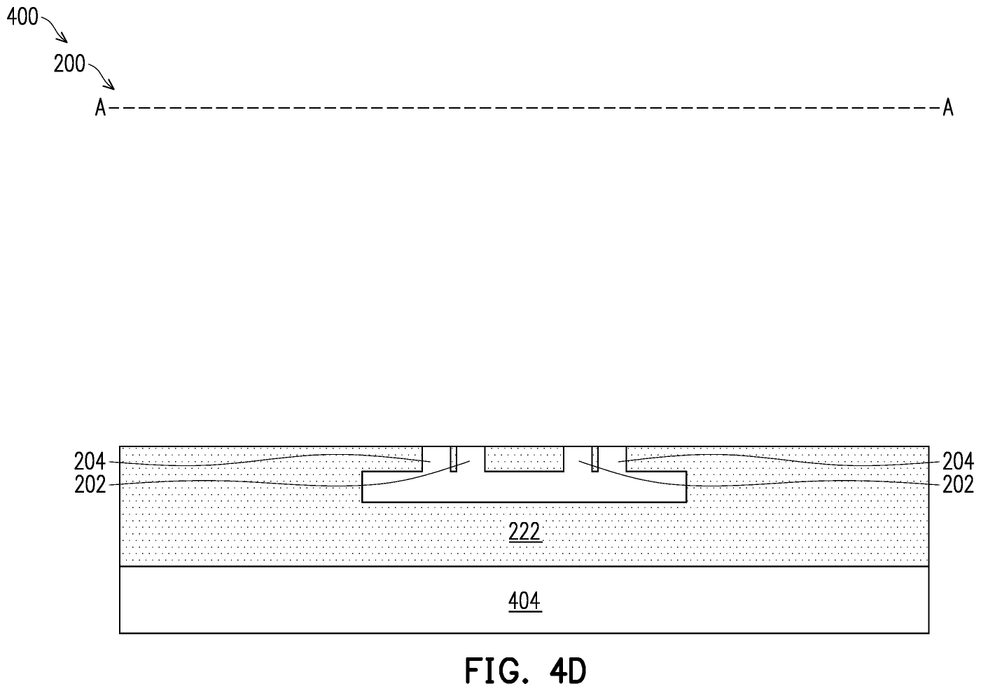

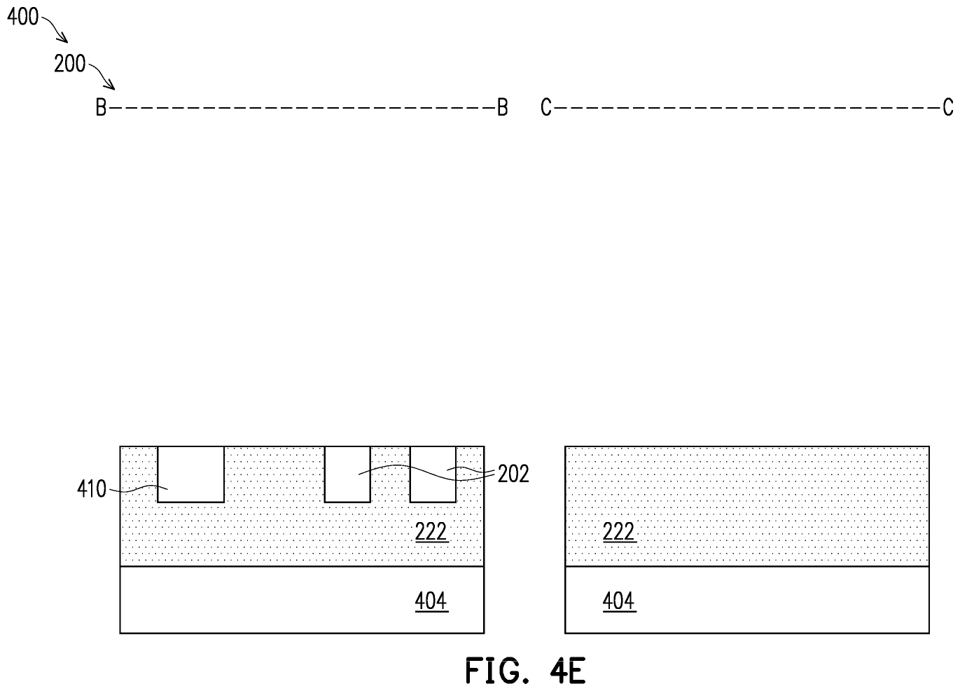

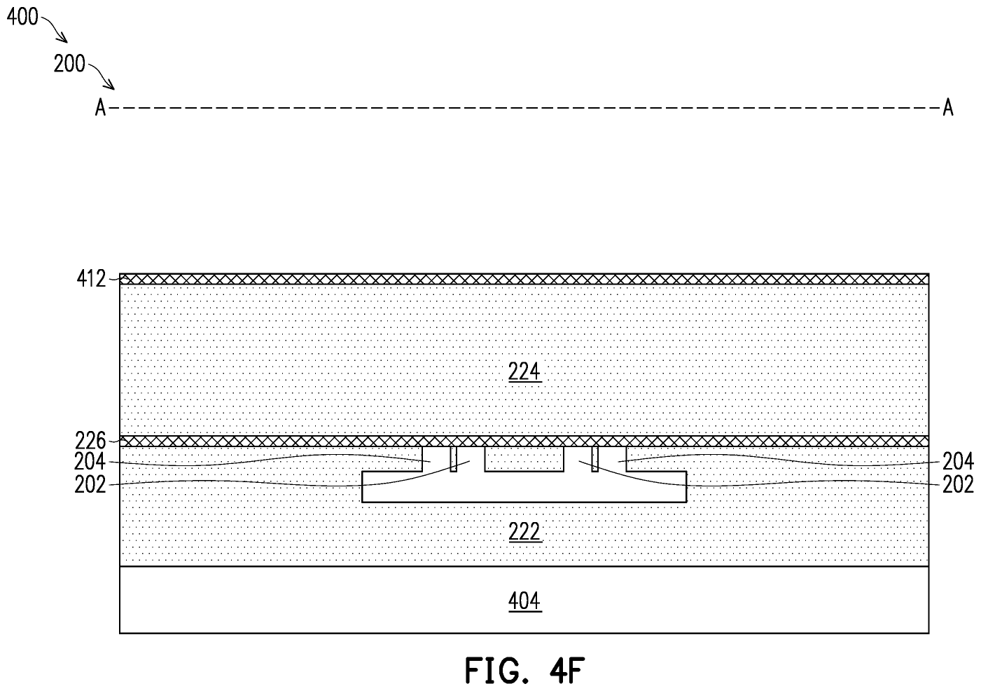

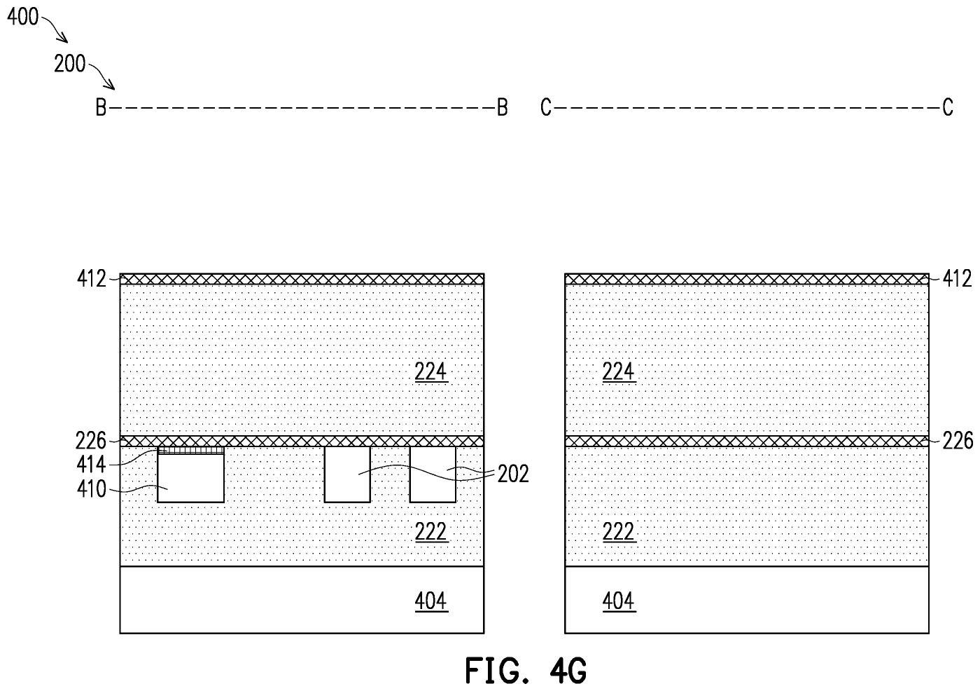

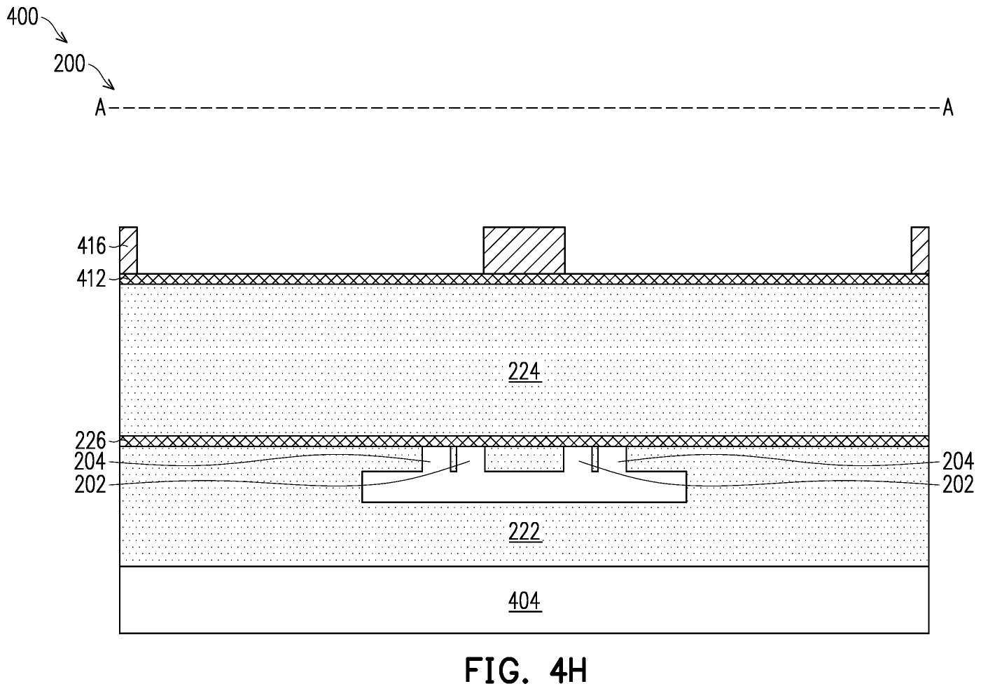

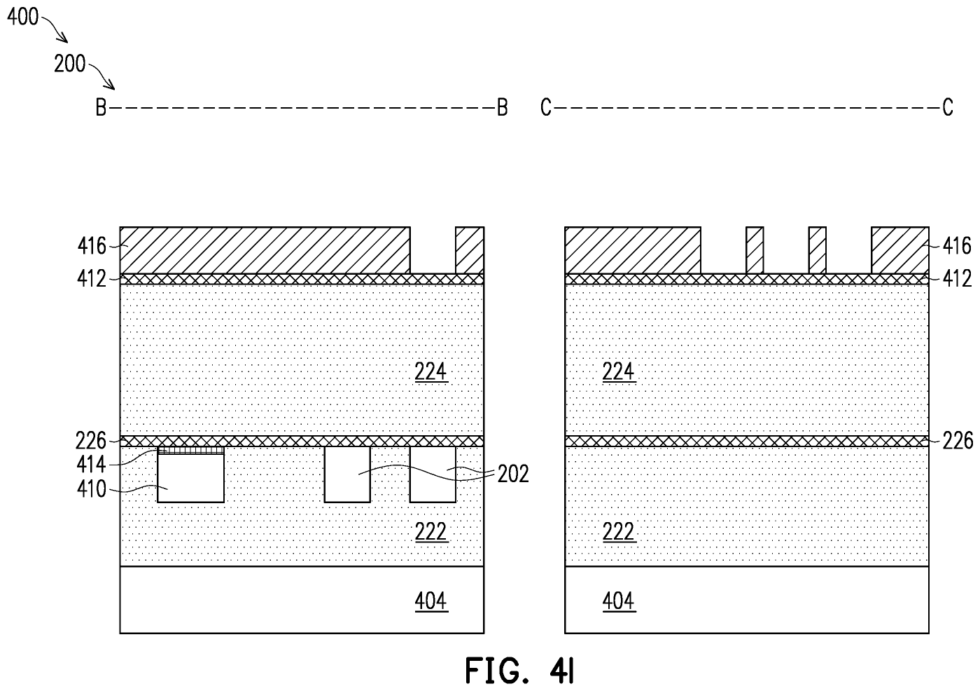

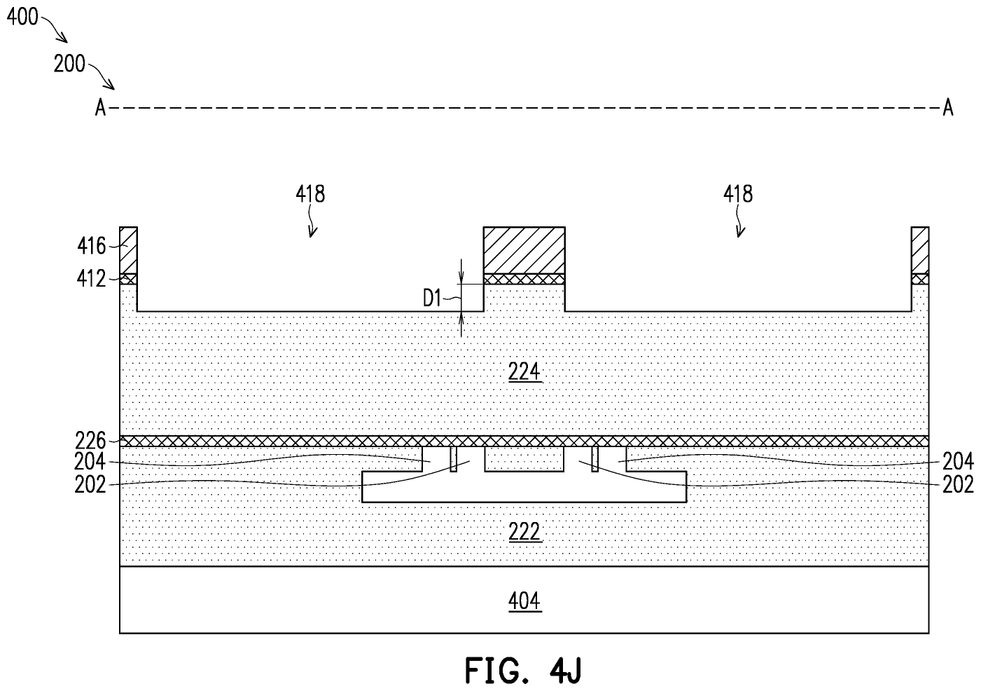

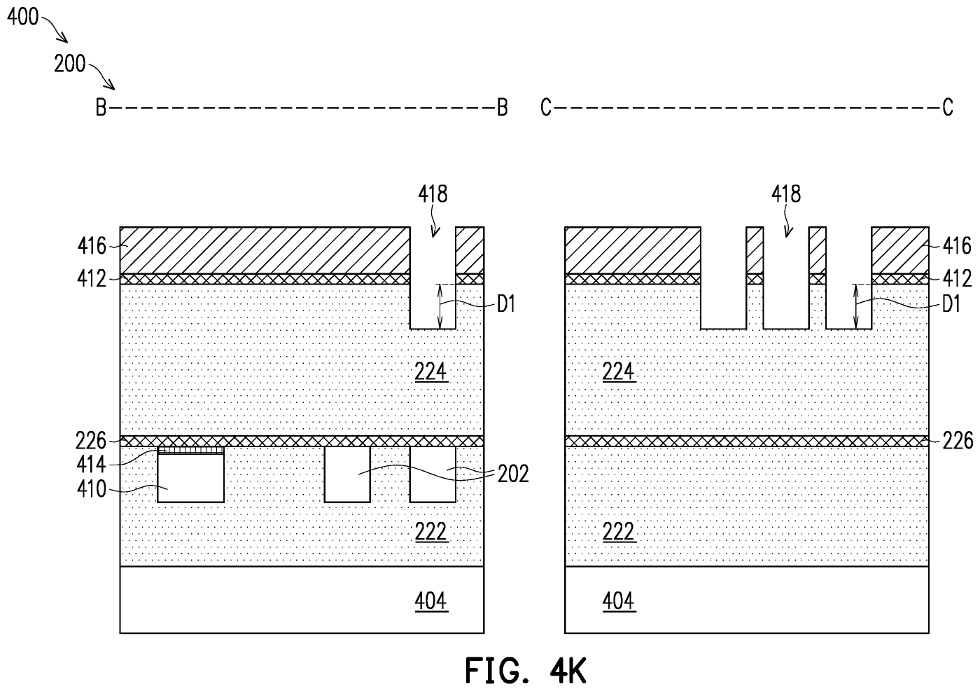

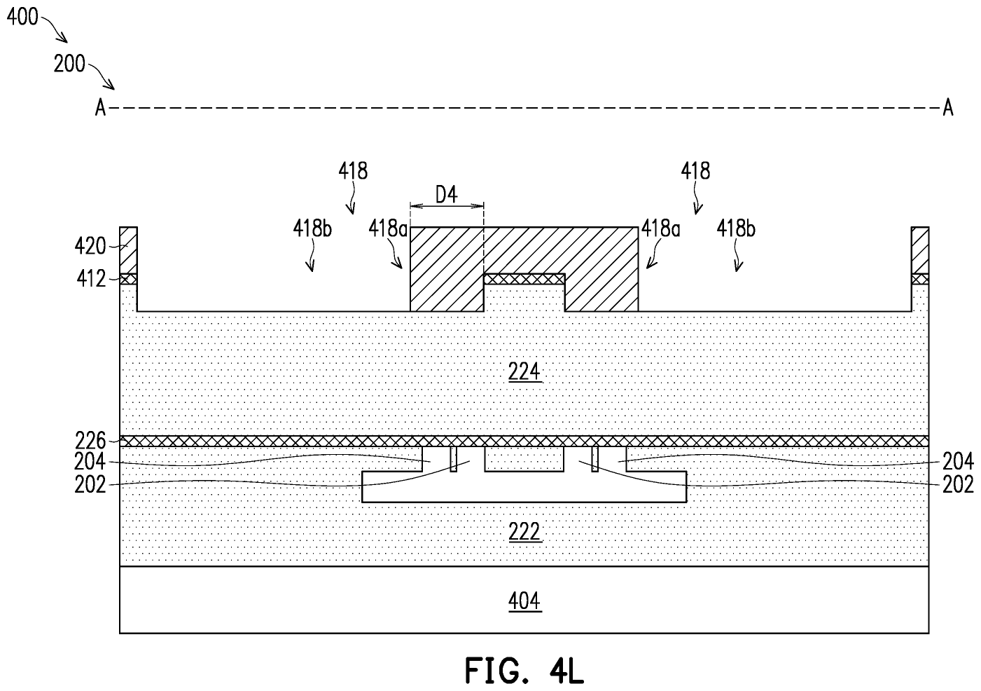

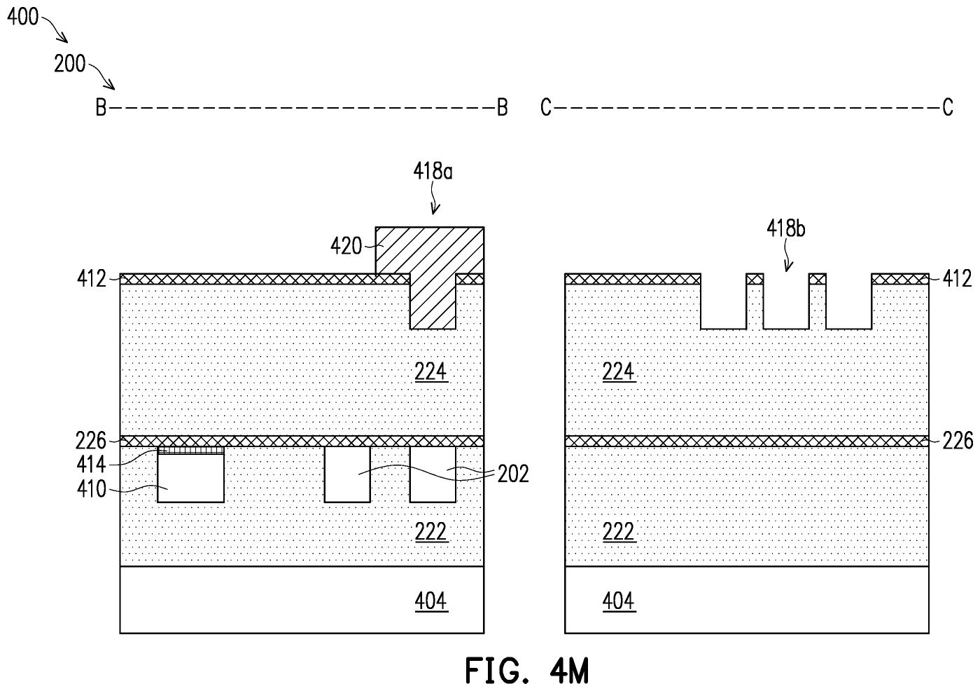

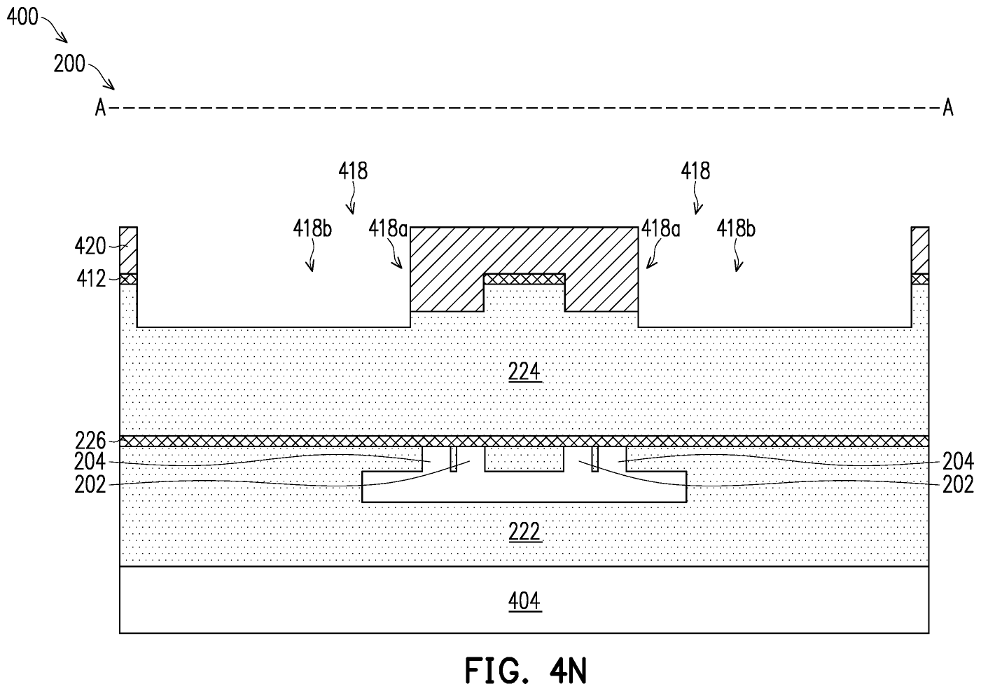

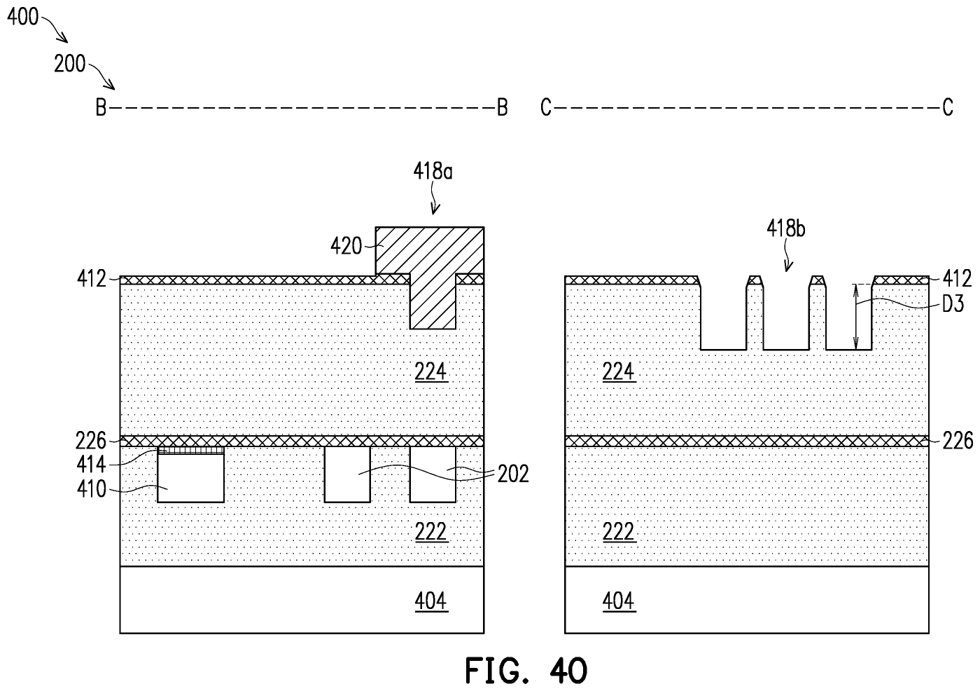

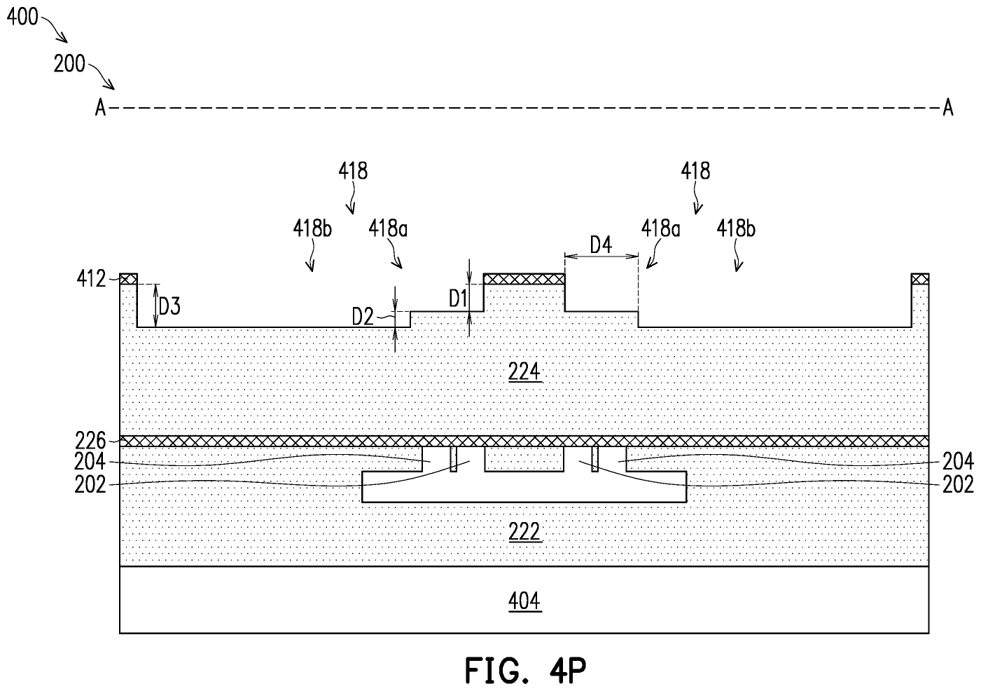

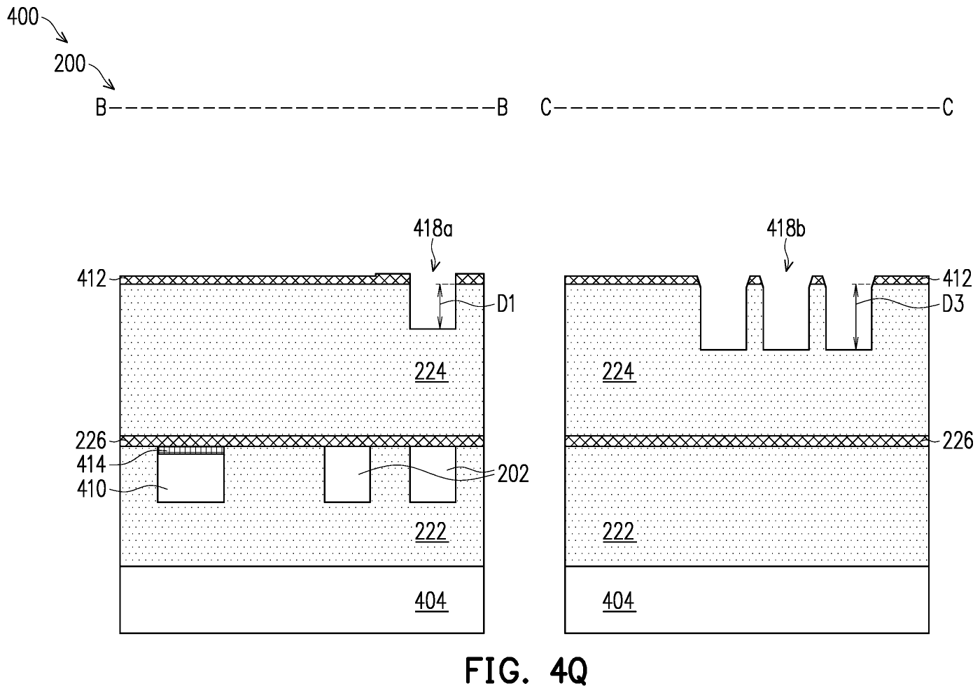

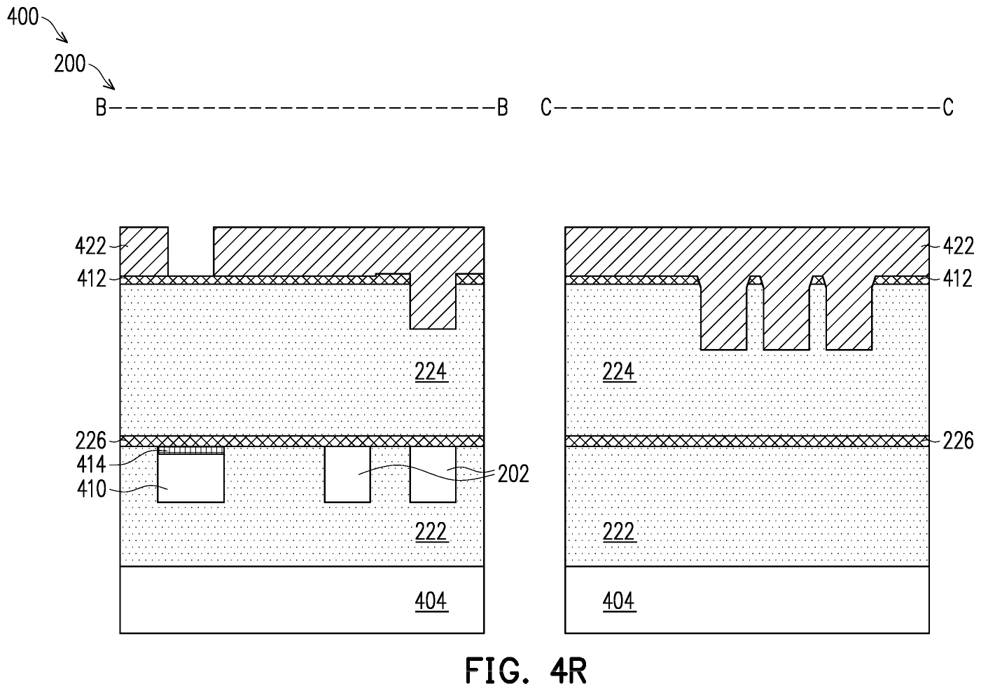

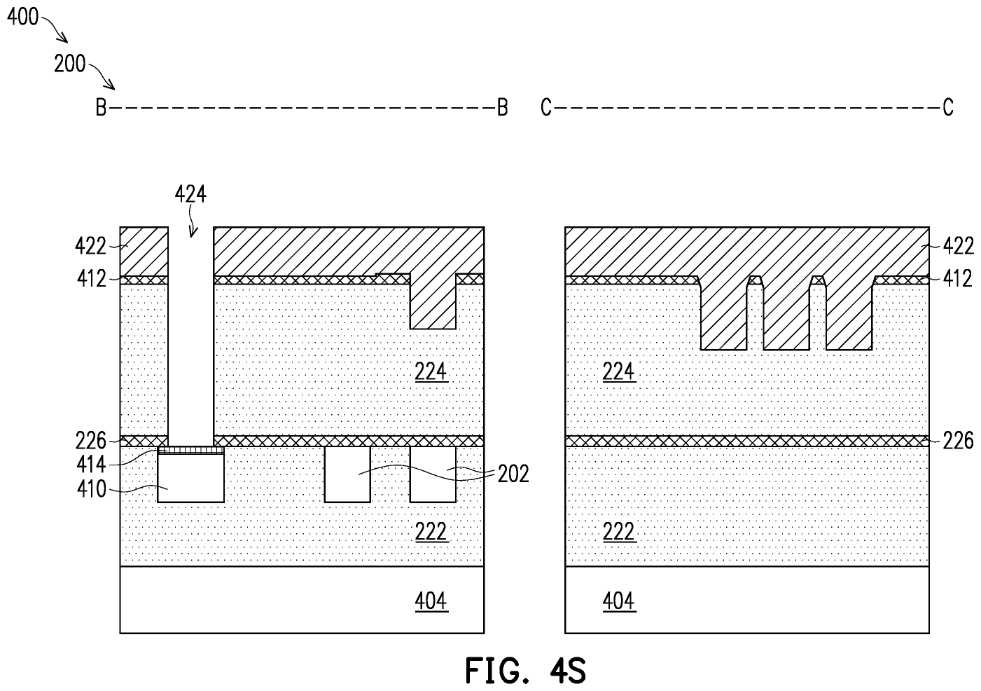

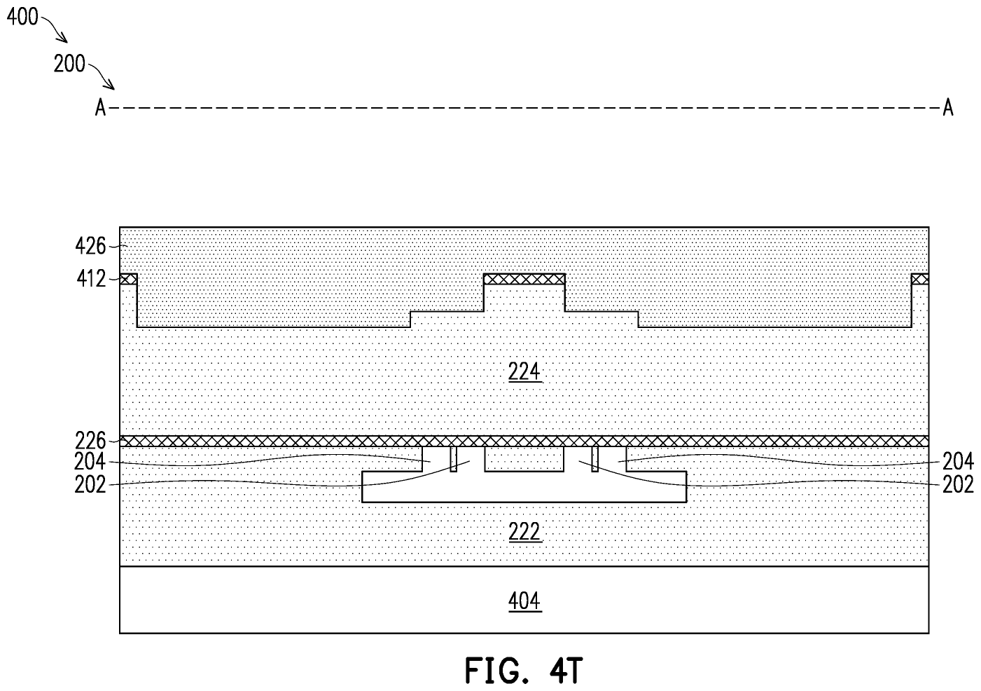

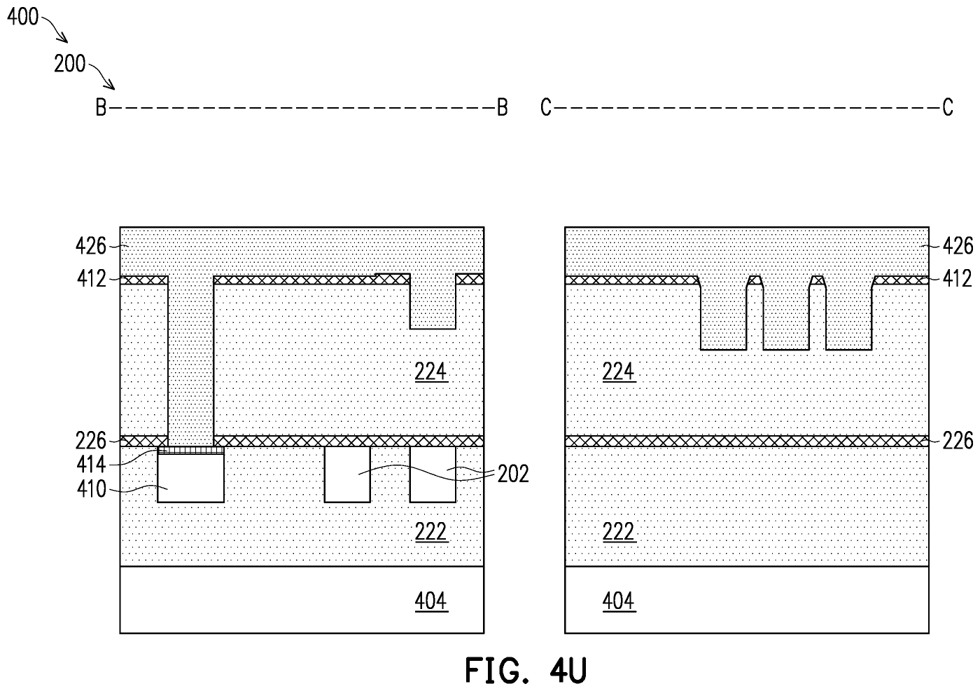

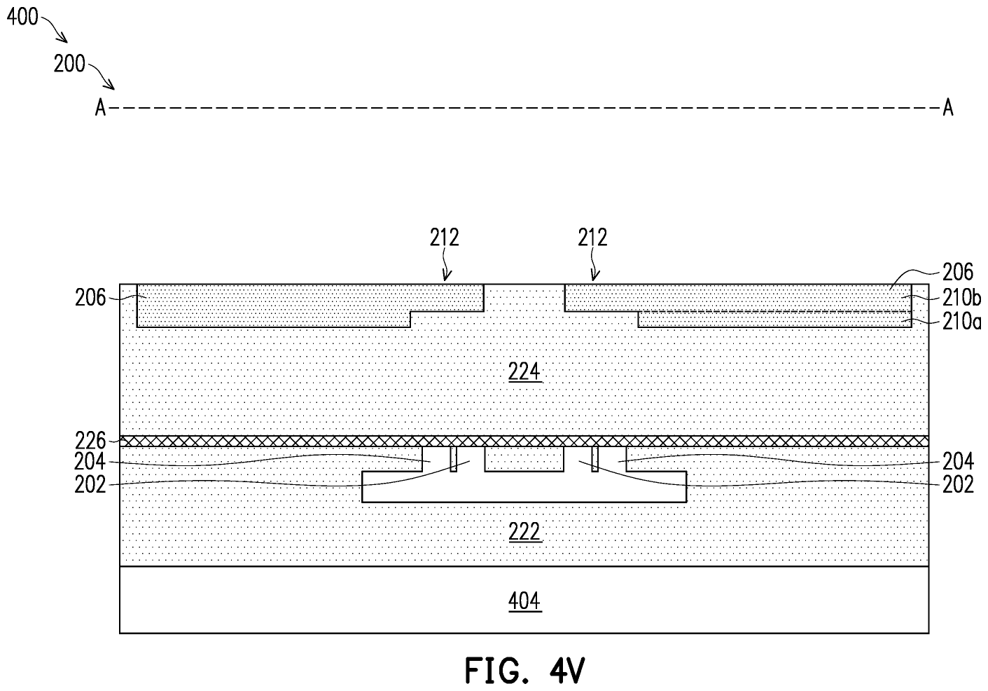

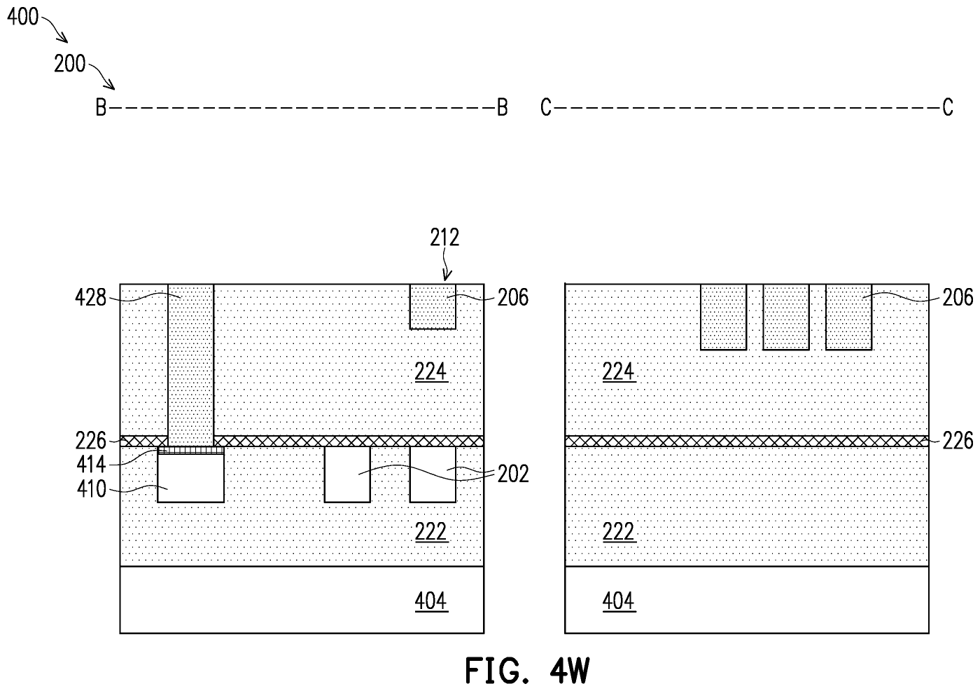

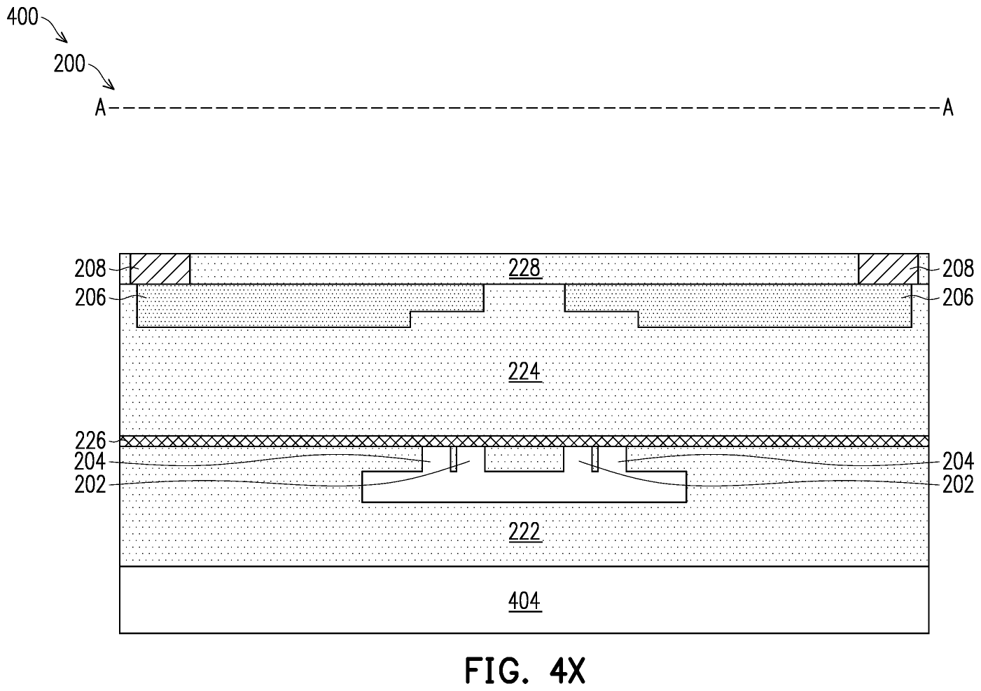

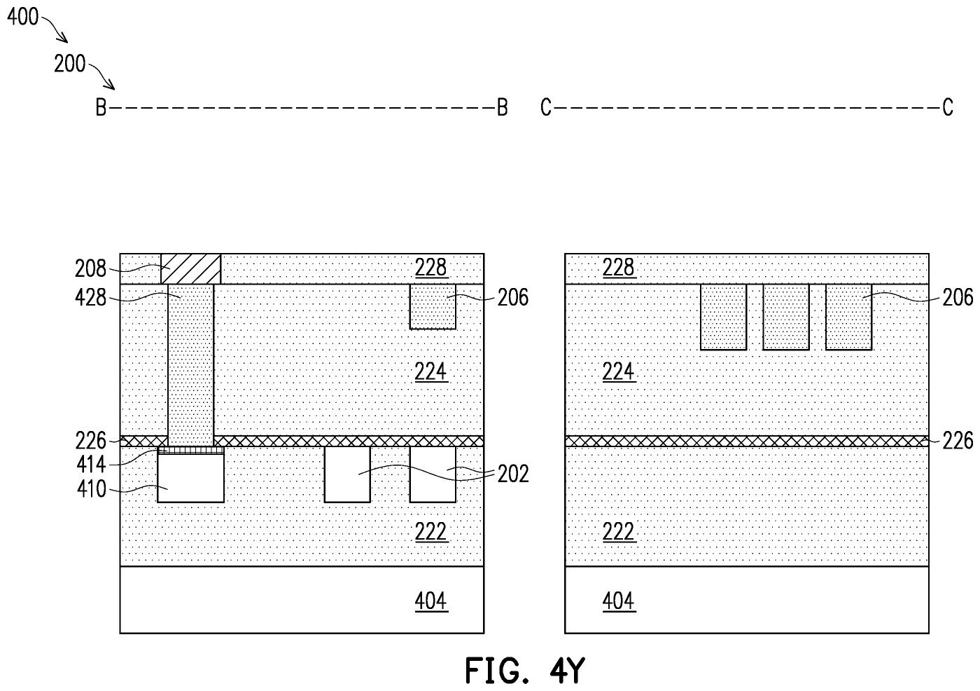

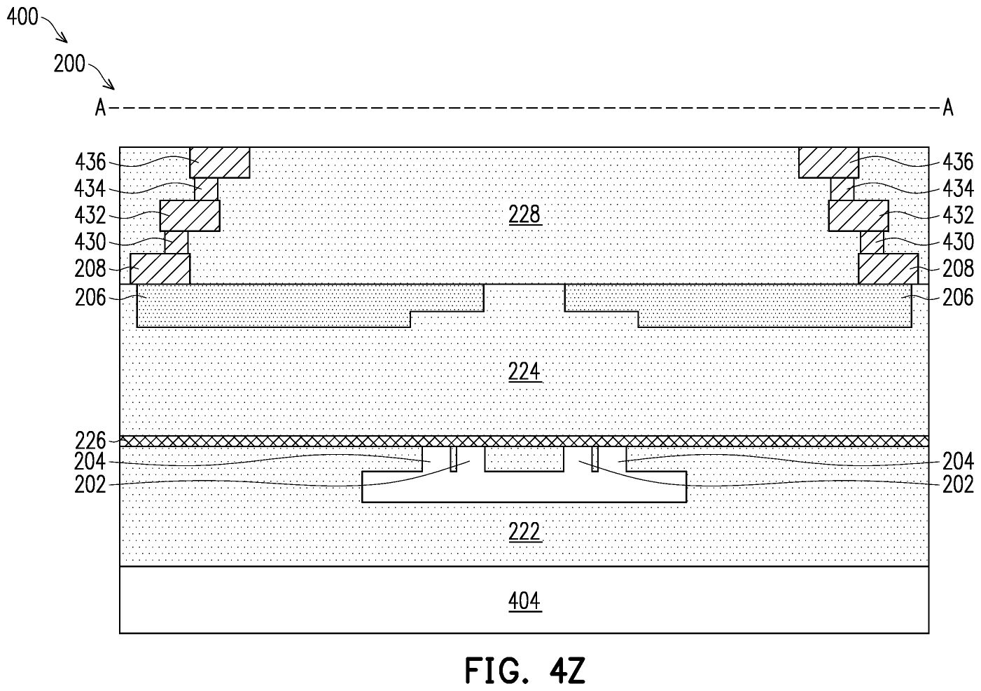

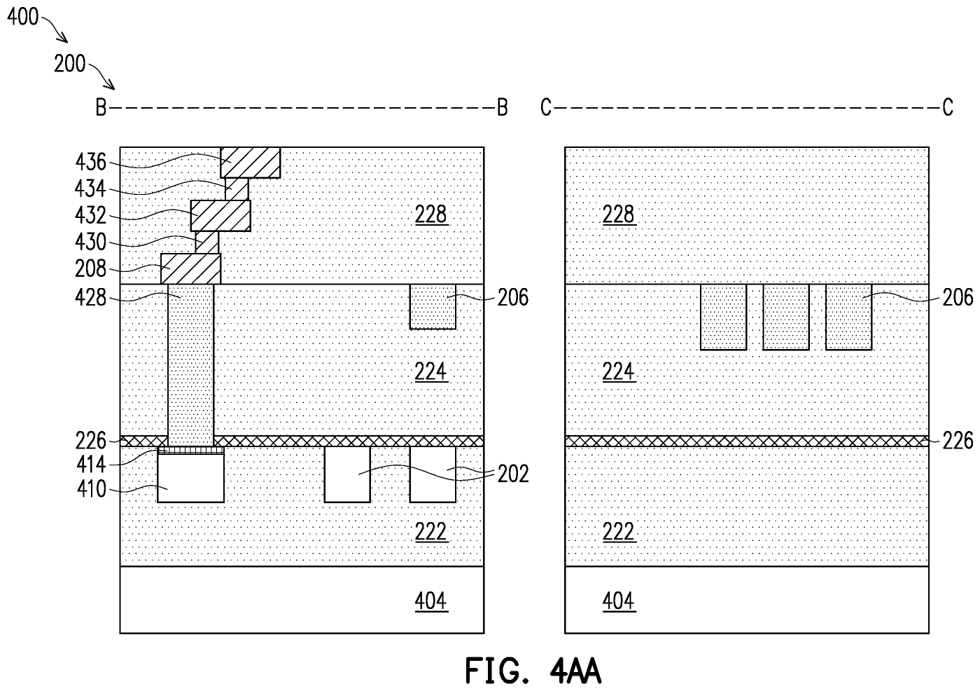

In some implementations, one or more of the semiconductor processing tools 102-114 may perform one or more semiconductor processing operations described herein. For example, one or more of the semiconductor processing tools 102-114 may form, in a semiconductor layer above a first dielectric layer, an optical modulator structure and a waveguide structure adjacent to the optical modulator structure; form an etch stop layer over the first dielectric layer, over the optical modulator structure, and over the waveguide structure; form a second dielectric layer over the etch stop layer; and form a modulator heater structure in the second dielectric layer, wherein a heater ring of the modulator heater structure is formed over the optical modulator structure, wherein a heater pad of the modulator heater structure, coupled with the heater ring, extends laterally outward from the heater ring, and wherein a thickness of the heater pad is greater relative to a thickness of the heater ring. One or more of the semiconductor processing tools 102-114 may perform other semiconductor processing operations described herein, such as in connection with FIGS. 4A-4AA, 6A-6U, and/or 8, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

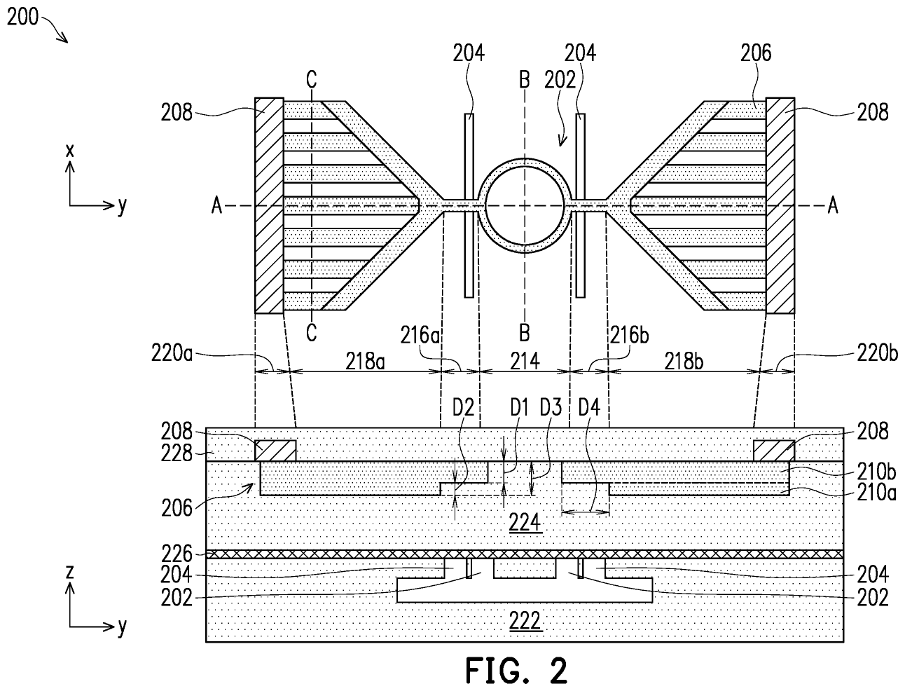

FIG. 2 is diagram of an example semiconductor device 200 described herein. The semiconductor device 200 may include a semiconductor photonics device and/or another type of semiconductor device that includes one or more photonic integrated circuits.

FIG. 2 illustrates a top-down view of the semiconductor device 200 and a corresponding cross-section view along line A-A in the top-down view. The semiconductor device 200 may be configured to use optical signals for high speed and secure data transmission between integrated circuits and/or semiconductor dies of the semiconductor device 200. Accordingly, the semiconductor device 200 may include an optical modulator structure 202 and one or more waveguide structures 204. An optical signal may be transferred through a waveguide structure 204 in the semiconductor device 200. The waveguide structure 204 enables confinement of the optical signal, which may reduce optical loss and increase propagation efficiency for the optical signal. Data may be encoded into an optical signal by modulating light into optical pulses in the optical modulator structure 202. The optical pulses are then transferred to a waveguide structure 204 for propagation to other regions of the semiconductor device 200. The optical modulator structure 202 and the waveguide structure(s) 204 may be adjacent and/or side by side in the semiconductor device 200 to enable coupling of the optical signal from the optical modulator structure 202 to the waveguide structure(s) 204 (and vice-versa for demodulation of an optical signal).

The optical modulator structure 202 may include an approximately circular shape, and may be referred to as a micro-ring modulator (MRM). The optical modulator structure 202 may function as a resonance chamber and may modulate an input signal from a light source to generate an optical signal (e.g., a modulated light signal). The optical signal may couple to the waveguide structure(s) 204 based on the optical signal achieving a threshold modulation frequency and/or based on the optical signal achieving a threshold signal intensity. A waveguide structure 204 may facilitate propagation of the optical signal to another device or area in the semiconductor device 200. In some implementations, the optical modulator structure 202 includes one or more doped regions. The one or more doped regions may facilitate and/or promote the flow of electrons in the optical modulator structure 202 and/or may facilitate and/or promote formation of an optical signal from an electrical signal. For example, the one or more doped regions may be configured as a p-n junction that is configured to generate an optical signal.

As further shown in FIG. 2, the semiconductor device 200 may include a modulator heater structure 206. The modulator heater structure 206 may be included above the optical modulator structure 202 and/or above the waveguide structure 204. As described above, the resonant wavelengths of the optical modulator structure 202 may be sensitive to variations in operating temperature. Thus, the modulator heater structure 206 may be configured to stabilize the operating temperature of the optical modulator structure 202 during operation of the optical modulator structure 202. In particular, the modulator heater structure 206 may heat (e.g., may increase the temperature of) the optical modulator structure 202 to an operating temperature setpoint or to a temperature in an operating temperature range, thereby stabilizing the operating performance of the optical modulator structure 202. The modulator heater structure 206 may include tungsten (W), titanium nitride (TiN), and/or another material that is capable of radiating heat toward the optical modulator structure 202.

The modulator heater structure 206 may be electrically coupled and/or physically coupled with one or more back end of line (BEOL) interconnect layers 208. The BEOL interconnect layer(s) 208 may be configured to provide an electrical current to the modulator heater structure 206. The BEOL interconnect layer(s) 208 may each include tungsten (W), cobalt (Co), ruthenium (Ru), titanium (Ti), aluminum (Al), copper (Cu) or gold (Au), among other examples of conductive materials. The BEOL interconnect layer(s) 208 may each include vias, trenches, contact plugs, and/or another type of metallization layers.

As further shown in the cross-sectional view of the semiconductor device 200 along the line A-A in FIG. 2, the modulator heater structure 206 may include a lower portion 210a (e.g., a first heater portion) and an upper portion 210b (e.g., a second heater portion) over the lower portion. The lower portion 210a and the upper portion 210b may be formed as a singular body (e.g., in a same set of one or more deposition operations) or may be formed in separate sets of one or more deposition operations such that a seam or material interface is located between the lower portion 210a and the upper portion 210b.

The upper portion 210b may extend laterally outward from an end or a sidewall of the lower portion 210a such that the modulator heater structure 206 includes an overhang section 212. The overhang section 212 results in a stepped inner end portion for the modulator heater structure 206. The overhang section 212 may be located above and/or over the optical modulator structure 202 and the waveguide structure 204. At least a portion of the overhang section 212 may correspond to a heater ring 214 that is located directly over the optical modulator structure 202. Thus, the heater ring 214 may include only the upper portion 210b of the modulator heater structure 206. The overhang section 212 results in the heater ring 214 having a lesser thickness than other portions of the modulator heater structure 206 that include both the lower portion 210a and the upper portion 210b. The lesser thickness of the heater ring 214 enables the heater ring 214 to be quickly and efficiently heated to provide heat to the optical modulator structure 202.

The optical modulator structure 202 may further include connection regions 216a and 216b electrically coupled and/or physically coupled with opposing sides of the heater ring 214, heater pads 218a and 218b respectively electrically coupled and/or physically coupled with the connection regions 216a and 216b, and contact regions 220a and 220b respectively electrically coupled and/or physically coupled with the heater pads 218a and 218b. The heater pad 218a may couple the connection region 216a and the contact region 220a, and the heater pad 218b may couple the connection region 216b the contact region 220b. The connection region 216a may couple the heater ring 214 and the heater pad 218a, and the connection region 216b may couple the heater ring 214 and the heater pad 218b. The connection regions 216a and 216b, the heater pads 218a and 218b, and the contact regions 220a and 220b being located on opposing sides of the heater ring 214 enables the heater ring 214 to be uniformly heated to provide uniform heat distribution across the optical modulator structure 202. However, other configurations for connection structure(s), heater pad(s), and/or contact region(s) are within the scope of the present disclosure.

The connection region 216a, the heater pad 218a, and the contact region 220a may enable an electrical current or another type of electrical input to be provided from a BEOL interconnect layer 208 to the heater ring 214 through the contact region 220a, the heater pad 218a, and the connection regions 216a. Similarly, the connection region 216b, the heater pad 218b, and the contact region 220b may enable an electrical current or another type of electrical input to be provided from another BEOL interconnect layer 208 to the heater ring 214 through the contact region 220b, the heater pad 218b, and the connection regions 216b.

The heater pads 218a and/or 218b may include the lower portion 210a and the upper portion 210b of the modulator heater structure 206. Thus, the thickness of the heater pads 218a and/or 218b may be greater than the thickness of the heater ring 214. In the cross-section view along line A-A in FIG. 2, a bottom surface of the heater pad 218a and/or 218b may be located closer to the etch stop layer 226 than a bottom surface of the heater ring 214 because of the greater thickness of the heater pads 218a and/or 218b, and because the top surfaces of the heater ring 214 and the top surfaces of the heater pads 218a and/or 218b may be approximately co-planar in the semiconductor device 200. The greater thickness of the heater pads 218a and/or 218b results in less electrical resistance in the heater pads 218a and/or 218b than the heater ring 214. This enables a high amount of electrical current to be provided to the heater ring 214 through the heater pads 218a and/or 218b with less heat dissipation in the heater pads 218a and/or 218b than the heater ring 214. In this way, the greater thickness of the heater pads 218a and/or 218b and the lesser thickness of the heater ring 214 results in increased operational efficiency (e.g., due to the reduced heat dissipation in the heater pads 218a and/or 218b and increased heat dissipation in the heater ring 214) for the modulator heater structure 206 relative to a single-thickness modulator heater structure.

The heater pads 218a and/or 218b may be positioned such that the heater pads 218a and/or 218b are not located directly over the optical modulator structure 202 and/or the waveguide structure 204. This enables the heater ring 214 to instead be located directly over the optical modulator structure 202 and/or the waveguide structure 204, thereby enabling the optical modulator structure 202 to be heated using the more efficient heat dissipation of the heater ring 214 (e.g., relative to the heater pads 218a and/or 218b).

The heater ring 214 may include a ring-shaped structure in the top-down view of the semiconductor device 200 and/or may substantially conform to the top-down shape of the optical modulator structure 202. The top-down shape of the heater pad 218a (and/or similarly for the heater pad 218b) may be tapered between the contact region 220a (and/or similarly for the contact region 220b) and the connection region 216a (and/or similarly for the connection region 216b). The tapered top-down shape of the heater pad 218a (and/or similarly for the heater pad 218b) provides low electrical resistance for a high amount of electrical current to flow through the heater pad 218a (and/or similarly for the heater pad 218b), and to enable the electrical current to be concentrated toward the heater ring 214 through the connection region 216a (and/or similarly for the connection region 216b). The heater pad 218a (and/or similarly for the heater pad 218b) may be tapered in a first direction (e.g., an x-direction) such that a top-down width of the heater pad 218a (and/or similarly for the heater pad 218b) reduces in a second direction (e.g., a y-direction) toward the connection region 216a (and/or similarly for the connection region 216b). The heater pad 218a (and/or similarly for the heater pad 218b) may further include, in the top-down view, a plurality of members that extend along the second direction (e.g., a y-direction) that is approximately perpendicular with the first direction (e.g., the x-direction). The members may be coupled with a BEOL interconnection layer 208 at a first end, and may be coupled with a V-shaped portion of the heater pad 218a (and/or similarly for the heater pad 218b) at a second end opposing the first end.

As further shown in FIG. 2, the modulator heater structure 206 may include one or more dimensions, such as a dimension D1, a dimension D2, a dimension D3, and/or a dimension D4, among other examples. The dimension D1 may correspond to a cross-sectional thickness (e.g., a z-direction thickness) of the upper portion 210b of the modulator heater structure 206. Moreover, the dimension D1 may correspond to a cross-sectional thickness (e.g., a z-direction thickness) of the heater ring 214. In some implementations, the dimension D1 is included in a range of approximately 80 nanometers to approximately 240 nanometers. Values less than approximately 80 nanometers for the dimension D1 may result in non-uniform heating of the optical modulator structure 202 because of process variations in forming the heater ring 214. Values greater than approximately 240 nanometers for the dimension D1 may result in insufficient electrical resistance in the heater ring 214 and, therefore, the heater ring 214 may not be able to sufficiently heat the optical modulator structure 202. However, ranges for the dimension D1 other than approximately 80 nanometers to approximately 240 nanometers may be used and are within the scope of the present disclosure.

The dimension D2 may correspond to a cross-sectional thickness (e.g., a z-direction thickness) of the lower portion 210a of the modulator heater structure 206. In some implementations, the dimension D2 is included in a range of approximately 0.5 times the dimension D1 to approximately 1.5 times the dimension D1 to achieve a sufficiently low electrical resistance in the heater pads 218a and/or 218b, which enables a high energy efficiency to be achieved for the modulator heater structure 206. However, ranges for the dimension D2 other than approximately 0.5 times the dimension D1 to approximately 1.5 times the dimension D1 may be used and are within the scope of the present disclosure.

The dimension D3 may correspond to a cross-sectional thickness (e.g., a z-direction thickness) of the heater pads 218a and/or 218b of the modulator heater structure 206. Thus, the dimension D3 may correspond to a combined thickness of the lower portion 210a (e.g., the dimension D1) and the upper portion 210b (e.g., the dimension D2) of the modulator heater structure 206. In some implementations, the dimension D3 is included in a range of approximately 120 nanometers to approximately 600 nanometers to achieve a sufficiently low electrical resistance in the heater pads 218a and/or 218b, which enables a high energy efficiency to be achieved for the modulator heater structure 206. However, ranges for the dimension D3 other than approximately 120 nanometers to approximately 600 nanometers may be used and are within the scope of the present disclosure.

The dimension D4 may correspond to a cross-sectional width (e.g., a y-direction width) of the overhang section 212 of the modulator heater structure 206. In some implementations, the dimension D4 is included in a range of approximately 0.3 microns to approximately 2 microns. Values less than approximately 0.3 microns for the dimension D4 may result in non-uniform heating of the optical modulator structure 202 because of process variations in forming the heater ring 214. Values greater than approximately 2 microns for the dimension D4 may result in insufficient electrical resistance in the heater ring 214 and, therefore, the heater ring 214 may not be able to sufficiently heat the optical modulator structure 202. However, ranges for the dimension D4 other than approximately 0.3 microns to approximately 2 microns may be used and are within the scope of the present disclosure.

As further shown in the cross-sectional view of the semiconductor device 200 along the line A-A in FIG. 2, the semiconductor device 200 may include a plurality of dielectric layers, such as a dielectric layer 222, a dielectric layer 224 above the dielectric layer 222, an etch stop layer 226 between the dielectric layer 222 and the dielectric layer 224, and/or a dielectric layer 228 above the dielectric layer 224. The dielectric layers 222 and 224, and the etch stop layer 226, may be included in a front end of line (FEOL) region of the semiconductor device 200. The dielectric layer 228 may be included in a BEOL region of the semiconductor device 200. The FEOL region may include the active semiconductor devices or circuitry of the semiconductor device 200, such as the optical modulator structure 202. The optical modulator structure 202 and the waveguide structure 204 may be included in the dielectric layer 222, and the modulator heater structure 206 may be included in the dielectric layer 224. The BEOL region may include metallization layers (such as the BEOL interconnect layer(s) 208) of the semiconductor device 200 and may be configured for signal and/or power delivery for the active semiconductor devices in the FEOL region.

The dielectric layers 222, 224, and 228 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The etch stop layer 226 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

Accordingly, the semiconductor device 200 may include a first dielectric layer (e.g., the dielectric layer 222), an etch stop layer (e.g., the etch stop layer 226) over the first dielectric layer, a second dielectric layer (e.g., the dielectric layer 224) over the etch stop layer, an optical modulator structure 202 in the first dielectric layer, and a modulator heater structure 206 above the optical modulator structure 202 and included in the second dielectric layer. The modulator heater structure 206 may include a heater ring 214 directly over the optical modulator structure and a heater pad 218a and/or 218b coupled with the heater ring 214, where a thickness (e.g., a dimension D3) of the heater pad 218a and/or 218b is greater than a thickness (e.g., a dimension D1) of the heater ring 214.

Other cross-sectional lines, in addition to the cross-sectional line A-A, are illustrated in FIG. 2 and referenced in connection with one or more of FIGS. 4A-4AA. The cross-sectional line A-A is in the second direction (e.g., the y-direction) in the semiconductor device 200 and extends along the modulator heater structure 206. A cross-sectional line B-B is in the first direction (e.g., the x-direction) in the semiconductor device 200 and extends across the heater ring 214 of the modulator heater structure 206. A cross-sectional line C-C is in the first direction (e.g., the x-direction) in the semiconductor device 200 and extends across a heater pad 218a of the modulator heater structure 206.

As indicated above, FIG. 2 is provided as an example. Other examples may differ from what is described with regard to FIG. 2.

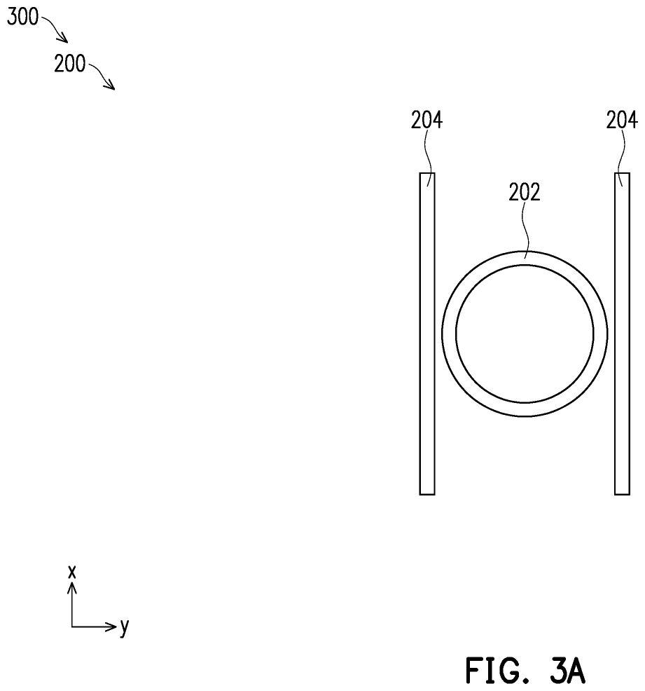

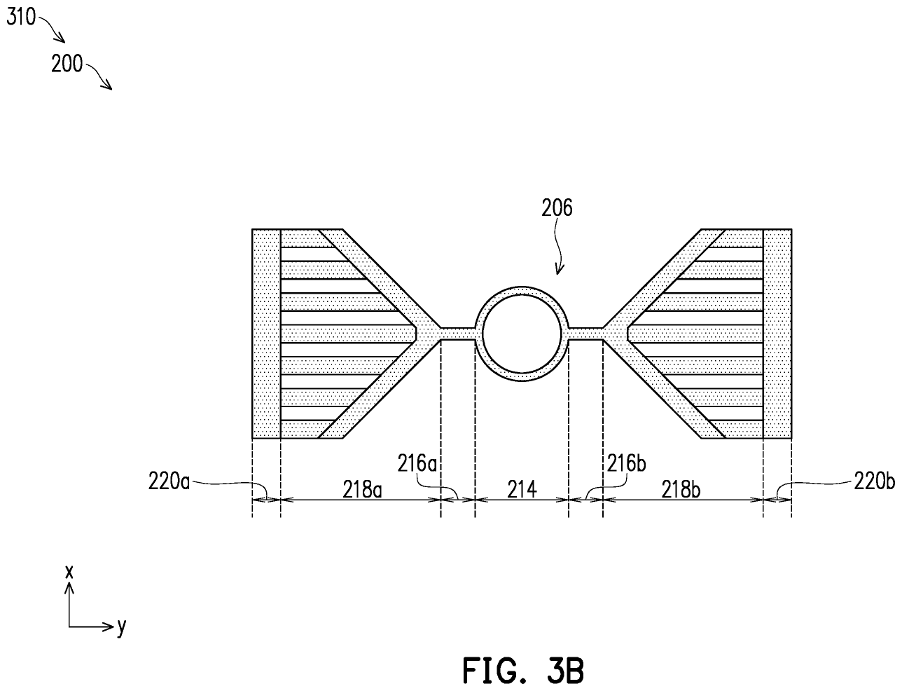

FIGS. 3A and 3B illustrate example implementations of one or more portions of the semiconductor device 200 described herein. FIG. 3A illustrates an example implementation 300 of the optical modulator structure 202 and a plurality of waveguide structures 204 that are located on opposing sides of the optical modulator structure 202. As shown in FIG. 3A, the optical modulator structure 202 may have an approximately ring-shaped or circular body. The waveguide structures 204 may have an approximately elongated shape that extends along a first direction (e.g., the x-direction in the semiconductor device 200).

FIG. 3B illustrates an example implementation 310 of the modulator heater structure 206. As shown in FIG. 3B, the heater ring 214 may include a ring-shaped structure in the top-down view of the semiconductor device 200 and/or may substantially conform to the top-down shape of the optical modulator structure 202. The top-down shape of the heater pad 218a (and/or similarly for the heater pad 218b) may be tapered between the contact region 220a (and/or similarly for the contact region 220b) and the connection region 216a (and/or similarly for the connection region 216b). The tapered top-down shape of the heater pad 218a (and/or similarly for the heater pad 218b) provides low electrical resistance for a high amount of electrical current to flow through the heater pad 218a (and/or similarly for the heater pad 218b), and to enable the electrical current to be concentrated toward the heater ring 214 through the connection region 216a (and/or similarly for the connection region 216b). The heater pad 218a (and/or similarly for the heater pad 218b) may be tapered in the first direction (e.g., an x-direction) such that a top-down width of the heater pad 218a (and/or similarly for the heater pad 218b) reduces in a second direction (e.g., a y-direction) toward the connection region 216a (and/or similarly for the connection region 216b). The heater pad 218a (and/or similarly for the heater pad 218b) may further include, in the top-down view, a plurality of members that extend along the second direction (e.g., a y-direction) that is approximately perpendicular with the first direction (e.g., the x-direction). The members may be coupled with a BEOL interconnection layer 208 at a first end, and may be coupled with a V-shaped portion of the heater pad 218a (and/or similarly for the heater pad 218b) at a second end opposing the first end.

As indicated above, FIGS. 3A and 3B is provided as examples. Other examples may differ from what is described with regard to FIGS. 3A and 3B.

FIGS. 4A-4AA are diagrams of an example implementation 400 of forming the semiconductor device 200 (or a portion thereof) described herein. In some implementations, one or more of the semiconductor processing operations described in connection with the example implementation 400 may be performed using one or more of the semiconductor processing tools 102-114 and/or by the wafer/die transport tool 116. In some implementations, one or more of the semiconductor processing operations described in connection with the example implementation 400 may be performed using another semiconductor processing tool.

Turning to FIG. 4A, a substrate 402 may be provided. The substrate 402 may include a silicon on insulator (SOI) substrate that includes a semiconductor substrate 404 (e.g., a silicon (Si) substrate and/or another type of semiconductor substrate), a dielectric layer 406 (e.g., a buried oxide or bottom oxide (BOX) layer and/or another type of insulator layer) over and/or on the semiconductor substrate 404, and a semiconductor layer 408 (e.g., a silicon (Si) layer and/or another type of semiconductor layer) over and/or on the dielectric layer 406. Alternatively, the semiconductor substrate 404 may be provided as a semiconductor wafer, and the deposition tool 102 may be used to form the dielectric layer 406 over and/or on the semiconductor substrate 404, and another deposition tool 102 may be used to form the semiconductor layer 408 over and/or on the dielectric layer 406. A deposition tool 102 may be used to form the dielectric layer 406 using a CVD technique, a PVD technique, an oxidation technique (e.g., a thermal oxidation technique), and/or another type of deposition technique. A deposition tool 102 may be used to form the semiconductor layer 408 using a CVD technique, a PVD technique, an epitaxy technique, and/or another type of deposition technique.

As shown in FIGS. 4B and 4C, the optical modulator structure 202 and the waveguide structure 204 may be formed in the semiconductor layer 408. As shown in FIG. 4C, a contact structure 410 may also be formed in the semiconductor layer 408. The contact structure 410 may be formed adjacent to the optical modulator structure 202 and may be used to provide an electrical input to the optical modulator structure 202 for generating a modulated optical signal.

In some implementations, a pattern in a masking layer (e.g., a hard mask layer, a photoresist layer) is used to etch the semiconductor layer 408 to form the optical modulator structure 202, the waveguide structure 204, and/or the contact structure 410. The deposition tool 102 may be used to form the masking layer on the semiconductor layer 408 (e.g., using a CVD technique, a PVD technique, and/or another type of deposition technique). An exposure tool 104 and an etch tool 108 may be used to remove portions of the masking layer to form the pattern in the masking layer. An etch tool 108 may then be used to perform an etch operation to etch the semiconductor layer 408 based on the pattern in the masking layer to form the optical modulator structure 202, the waveguide structure 204, and/or the contact structure 410. In some implementations, the etch operation includes a plasma etch operation, a wet chemical etch operation, and/or another type of etch operation. In some implementations, a photoresist removal tool is used to remove the remaining portions of the masking layer (e.g., using a chemical stripper, plasma ashing, and/or another technique). In some implementations, a planarization tool 110 is used to remove the remaining portions of the masking layer using a CMP technique and/or another type of planarization technique.

As shown in FIGS. 4D and 4E, dielectric material may be deposited over the dielectric layer 406 to encapsulate the optical modulator structure 202, the waveguide structure 204, and/or the contact structure 410 in the dielectric layer 222 of the semiconductor device 200. The deposition tool 102 may be used to deposit the dielectric material using a CVD technique, a PVD technique, an oxidation technique (e.g., a thermal oxidation technique), and/or another type of deposition technique. In some implementations, one or more additional semiconductor processing operations may be performed to deposit the additional material of the dielectric layer 222. For example, the deposition tool 102 may be used to perform a shallow trench isolation (STI) liner oxidation operation and/or a high density plasma (HDP) deposition operation to deposit the dielectric material of the dielectric layer 222. As another example, a planarization tool 110 may be used to perform a CMP operation and/or another type of planarization operation to planarize the dielectric layer 222 after the dielectric material. The CMP operation may result in top surfaces of the optical modulator structure 202, the waveguide structure 204, and/or the contact structure 410 being exposed through the dielectric layer 222.

In some implementations, one or more portions of the optical modulator structure 202 may be subsequently doped with one or more types of dopants to form one or more doped regions in the optical modulator structure 202. For example, the ion implantation tool 114 may be used (e.g., using an ion implantation technique and/or another type of doping technique) to implant one or more portions of the optical modulator structure 202 with p-type ions to form one or more p-type regions in the optical modulator structure 202. As another example, the ion implantation tool 114 may be used (e.g., using an ion implantation technique and/or another type of doping technique) to implant one or more portions of the optical modulator structure 202 with n-type ions to form one or more n-type regions in the optical modulator structure 202.

As shown in FIGS. 4F and 4G, one or more additional layers may be formed over and/or on the dielectric layer 222 after formation of the optical modulator structure 202, after formation of the waveguide structure 204, and/or after formation of the contact structure 410. For example, the etch stop layer 226 may be formed over and/or on the dielectric layer 222. As another example, the dielectric layer 224 may be formed over and/or on the etch stop layer 226. As another example, an etch stop layer 412 may be formed over and/or on the dielectric layer 224.

A deposition tool 102 may be used to deposit the etch stop layer 226, the dielectric layer 224, and/or the etch stop layer 412 in one or more PVD operations, one or more ALD operations, one or more CVD operations, one or more epitaxy operations, one or more oxidation operations, one or more deposition operations of another type described in connection with FIG. 1, and/or one or more deposition operations of another type. In some implementations, a planarization tool 110 planarizes the etch stop layer 226, the dielectric layer 224, and/or the etch stop layer 412 after a deposition tool 102 deposits the etch stop layer 226, the dielectric layer 224, and/or the etch stop layer 412.

As further shown in FIG. 4G, in some implementations, a silicide layer 414 may be formed over and/or on the top surface of the contact structure 410 prior to formation of the one or more additional layers. The silicide layer 414 may include a metal silicide layer that is included to achieve a relatively low contact resistance for the contact structure 410 and/or to reduce the likelihood of native oxides forming on the top surface of the contact structure 410. A deposition tool 102 may be used to deposit the silicide layer 414 using a CVD technique, a PVD technique, an ALD technique, and/or another deposition technique. In some implementations, a deposition tool 102 may be used to perform a pre-clean operation to remove oxides (e.g., native oxides) from the top surface of the contact structure 410 prior to formation of the silicide layer 414.

As shown in FIGS. 4H and 41, a masking layer 416 may be formed over and/or on the etch stop layer 412. The masking layer 416 may include a hard mask layer, a photoresist layer, and/or another type of masking layer. A deposition tool 102 may be used to deposit the masking layer 416 in one or more PVD operations, one or more ALD operations, one or more CVD operations, one or more epitaxy operations, one or more oxidation operations, one or more deposition operations of another type described in connection with FIG. 1, and/or one or more deposition operations of another type. A pattern may then be formed in the masking layer 416. In some implementations, the pattern may be formed by using an etch tool 108 to etch the masking layer 416 to remove portions of the masking layer 416.

As shown in FIGS. 4J and 4K, the masking layer 416 may be used to etch through the etch stop layer 412 and into a portion of the dielectric layer 224 to form a recess 418 in the dielectric layer 224. The recess 418 may be formed to a first depth corresponding to the dimension D1. An etch tool 108 may be used to perform an etch operation (e.g., a first etch operation) to etch the etch stop layer 412 and the dielectric layer 224 to form the recess 418. In some implementations, the etch operation includes a plasma etch operation, a wet chemical etch operation, and/or another type of etch operation. In some implementations, a photoresist removal tool is used to remove the remaining portions of the masking layer 416 (e.g., using a chemical stripper, plasma ashing, and/or another technique). In some implementations, a planarization tool 110 is used to remove the remaining portions of the masking layer 416 using a CMP technique and/or another type of planarization technique.

As shown in FIGS. 4L and 4M, a masking layer 420 (e.g., another masking layer) may be formed after the masking layer 416 is removed. The masking layer 420 may include a hard mask layer, a photoresist layer, and/or another type of masking layer. A deposition tool 102 may be used to deposit the masking layer 420 in one or more PVD operations, one or more ALD operations, one or more CVD operations, one or more epitaxy operations, one or more oxidation operations, one or more deposition operations of another type described in connection with FIG. 1, and/or one or more deposition operations of another type.

A pattern may then be formed in the masking layer 420. In some implementations, the pattern may be formed by using an etch tool 108 to etch the masking layer 420 to remove portions of the masking layer 420. The remaining portions of the masking layer 420 may cover portions 418a of the recess 418 over the optical modulator structure 202 and over the waveguide structure 204. Portions 418b of the recess 418 that are not over the optical modulator structure 202 and the waveguide structure 204 may be exposed through the pattern in the masking layer 420.

As shown in FIGS. 4N and 4O, the portions 418b (e.g., the exposed portions) of the recess 418 may be etched using the masking layer 420 over the portions 418a of the recess 418 (e.g., such that the portions 418a are not etched). An etch tool 108 may be used to perform an etch operation (e.g., a second etch operation after the first etch operation) to etch the dielectric layer 224 to increase the depth of the portions 418b of the recess 418 from the first depth (e.g., corresponding to the dimension D1) to a second depth corresponding to the dimension D3. In some implementations, the etch operation includes a plasma etch operation, a wet chemical etch operation, and/or another type of etch operation. The portions 418a remain at the first depth as a result of the portions 418a being covered by the masking layer 420.

As shown in FIGS. 4P and 4Q, a photoresist removal tool is used to remove the remaining portions of the masking layer 420 (e.g., using a chemical stripper, plasma ashing, and/or another technique). Additionally and/or alternatively, a planarization tool 110 is used to remove the remaining portions of the masking layer 420 using a CMP technique and/or another type of planarization technique. As further shown in FIGS. 4P and 4Q, the portions 418a of the recess 418 may be formed to the first depth (e.g., relative to a top surface of the dielectric layer 224) corresponding to the dimension D1. The portions 418b of the recess 418 may be formed to the second depth (e.g., relative to the top surface of the dielectric layer 224) corresponding to the dimension D3. The difference in depth between the portions 418a and the portions 418b may correspond to the dimension D2.

As shown in FIG. 4R, a masking layer 422 may be formed over and/or on the etch stop layer 412 and in the recess 418 such that the portions 418a and the portions 418b are covered by the masking layer 422. The masking layer 422 may include a hard mask layer, a photoresist layer, and/or another type of masking layer. A deposition tool 102 may be used to deposit the masking layer 422 in one or more PVD operations, one or more ALD operations, one or more CVD operations, one or more epitaxy operations, one or more oxidation operations, one or more deposition operations of another type described in connection with FIG. 1, and/or one or more deposition operations of another type. A pattern may then be formed in the masking layer 422. In some implementations, the pattern may be formed by using an etch tool 108 to etch the masking layer 422 to remove portions of the masking layer 422 over the contact structure 410.

As shown in FIG. 4S, the etch stop layer 412, the dielectric layer 224, and the etch stop layer 226 may be etched using the pattern in the masking layer 422 to form a recess 424 over the contact structure 410. The silicide layer 414 on the top surface of the contact structure 410 may be exposed through the recess. An etch tool 108 may be used to perform an etch operation to etch the etch stop layer 412, the dielectric layer 224, and the etch stop layer 226 to form the recess 424. In some implementations, the etch operation includes a plasma etch operation, a wet chemical etch operation, and/or another type of etch operation. In some implementations, a photoresist removal tool is used to remove the remaining portions of the masking layer 422 (e.g., using a chemical stripper, plasma ashing, and/or another technique). In some implementations, a planarization tool 110 is used to remove the remaining portions of the masking layer 422 using a CMP technique and/or another type of planarization technique.

As shown in FIGS. 4T and 4U, an electrically conductive material layer 426 may be formed in the recess 418 and in the recess 424. The electrically conductive material layer 426 may land on the silicide layer 414 that is on the top surface of the contact structure 410. The electrically conductive material layer 426 may include tungsten (W), titanium (Ti), copper (Cu), ruthenium (Ru), cobalt (Co), and/or another electrically conductive material. A deposition tool 102 and/or a plating tool 112 may be used to deposit the electrically conductive material layer 426 in one or more PVD operations, one or more ALD operations, one or more CVD operations, one or more electroplating operations, one or more deposition operations of another type described in connection with FIG. 1, and/or one or more deposition operations of another type. In some implementations, a seed layer is first deposited, and the electrically conductive material layer 426 is deposited on the seed layer.

As shown in FIGS. 4V and 4W, material may be removed from the electrically conductive material layer 426. The remaining portions of the electrically conductive material layer 426 may correspond to the modulator heater structure 206 (which may be formed in the recess 418) and an interconnect structure 428 (which may be formed in the recess 424 over the contact structure 410). A planarization tool 110 may be used to planarize the electrically conductive material layer 426 to remove the material from the electrically conductive material layer 426.

As shown in FIG. 4V, the modulator heater structure 206 may include the lower portion 210a and the upper portion 210b. The upper portion 210b may include the overhang section 212. The overhang section 212 of the upper portion 210b may be formed in the portions 418a of the recess 418 (e.g., over the optical modulator structure 202 and over the waveguide structure 204). The lower portion 210a and the upper portion 210b (e.g., other than the overhang section 212) may be formed in the portions 418b of the recess 418.

As shown in FIGS. 4X and 4Y, a portion of the BEOL region of the semiconductor device 200 may be formed over the FEOL region of the semiconductor device 200. For example, the dielectric layer 228 may be formed over and/or on the dielectric layer 224 and over and/or on the modulator heater structure 206. BEOL interconnect layers 208 may be formed in the dielectric layer 228. BEOL interconnect layers 208 may be formed over and/or on the modulator heater structure 206, and over and/or on the interconnect structure 428, among other examples. The BEOL interconnect layers 208 may be approximately co-planar and may be referred to as a metal-1 (M1) layer of the BEOL region.

A deposition tool 102 may be used to deposit the dielectric layer 228 in one or more PVD operations, one or more ALD operations, one or more CVD operations, one or more epitaxy operations, one or more oxidation operations, one or more deposition operations of another type described in connection with FIG. 1, and/or one or more deposition operations of another type. A deposition tool 102 and/or a plating tool 112 may be used to deposit the BEOL interconnect layers 208 in one or more PVD operations, one or more ALD operations, one or more CVD operations, one or more electroplating operations, one or more deposition operations of another type described in connection with FIG. 1, and/or one or more deposition operations of another type. In some implementations, a seed layer is first deposited, and the BEOL interconnect layers 208 are deposited on the seed layer. A planarization tool 110 may be used to perform a CMP operation and/or another type of planarization operation to planarize the BEOL interconnect layers 208.

As shown in FIGS. 4Z and 4AA, additional metallization layers of the BEOL region may be formed over and/or on the BEOL interconnect layers 208. For example, a BEOL interconnect layer 430 (e.g., a via-1 layer) may be formed over and/or on the BEOL interconnect layers 208. As another example, a BEOL interconnect layer 432 (e.g., a metal-2 or M2 layer) may be formed over and/or on the BEOL interconnect layers 430. As another example, a BEOL interconnect layer 434 (e.g., a via-2 layer) may be formed over and/or on the BEOL interconnect layers 432. As another example, a BEOL interconnect layer 436 (e.g., a metal-3 or M3 layer) may be formed over and/or on the BEOL interconnect layers 434.

A deposition tool 102 and/or a plating tool 112 may be used to deposit the BEOL interconnect layers 430-436 in one or more PVD operations, one or more ALD operations, one or more CVD operations, one or more electroplating operations, one or more deposition operations of another type described in connection with FIG. 1, and/or one or more deposition operations of another type. In some implementations, a seed layer is first deposited, and the BEOL interconnect layers 430-436 are deposited on the seed layer. A planarization tool 110 may be used to perform a CMP operation and/or another type of planarization operation to planarize the BEOL interconnect layers 430-436.

As indicated above, FIGS. 4A-4AA are provided as examples. Other examples may differ from what is described with regard to FIGS. 4A-4AA.

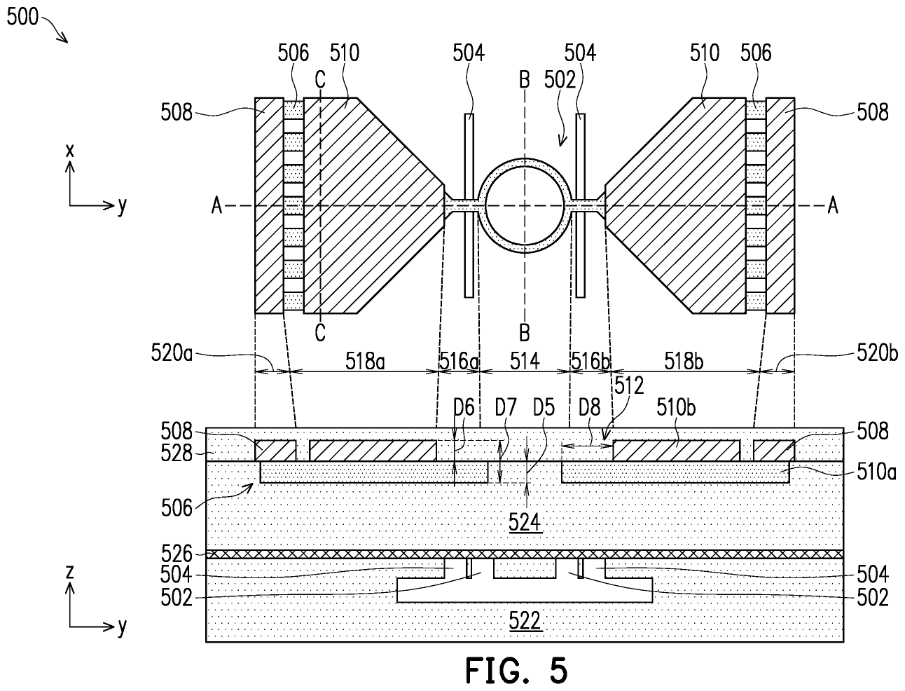

FIG. 5 is diagram of an example semiconductor device 500 described herein. The semiconductor device 500 may include a semiconductor photonics device and/or another type of semiconductor device that includes one or more photonic integrated circuits. FIG. 5 illustrates a top-down view of the semiconductor device 500 and a corresponding cross-section view along line A-A in the top-down view. The semiconductor device 500 may be configured to use optical signals for high speed and secure data transmission between integrated circuits and/or semiconductor dies of the semiconductor device 500.

As shown in FIG. 5, the semiconductor device 500 may include a similar arrangement of layers and/or structures as the semiconductor device 200 illustrated and described in connection with FIG. 2. For example, the semiconductor device 500 may include elements 502-528, which may be similar to elements 202-228 of the semiconductor device 200. However, instead of including a lower portion 210a and an upper portion 210b in the dielectric layer 224, the semiconductor device 500 includes a main portion 510a in the dielectric layer 524 and one or more extension portions 510b on the main portion 510a. The extension portion(s) 510b (also referred to as extension layers) may be included in the BEOL region of the semiconductor device 500 (e.g., in the dielectric layer 528) and may therefore be referred to as BEOL extension portion(s) of the modulator heater structure 506.

Extension portions 510b may be included over and/or on one or more of the heater pads 518a and/or 518b to effectively increase the thickness of the heater pads 518a and/or 518b. This enables a low electrical resistance to be achieved in the heater pads 518a and/or 518b. The main portion 510a may extend laterally outward from an end or inside edge of an extension portion 510b such that the modulator heater structure 506 includes an extension section 512 (which is inverted in the z-direction relative to the overhang section 212 of the modulator heater structure 206). The extension section 512 may correspond to the heater ring 514 of the modulator heater structure 506. The lesser thickness of the extension section 512 relative to the thickness of the combination of the main portion 510a and an extension portion 510b provides greater electrical resistance in the heater ring 514 than the electrical resistance in the heater pads 518a and/or 518b, which enables the heater ring 514 to efficiently generate heat that is to be provided to the optical modulator structure 502.

The main portion 510a and the extension portion(s) 510b of the modulator heater structure 506 may be formed during different processes of forming the semiconductor device 500. For example, the main portion 510a may be formed during an FEOL process and the extension portion(s) 510b may be formed during a BEOL process (e.g., along with the BEOL interconnect layers 508). Thus, the main portion 510a and the extension portion(s) 510b may be formed in separate sets of one or more deposition operations, resulting in a seam or material interface between the main portion 510a and the extension portion(s) 510b. In some implementations, the main portion 510a and the extension portion(s) 510b are formed of the same material or the same material composition. In some implementations, the main portion 510a and the extension portion(s) 510b are formed of different materials or different material compositions. For example, the main portion 510a may be formed of FEOL materials such as tungsten (W) and/or another electrically conductive FEOL material, and the extension portion(s) 510b may be formed of copper (Cu), ruthenium (Ru), cobalt (Co), and/or another BEOL electrically conductive material.

As further shown in FIG. 5, the modulator heater structure 206 may include one or more dimensions, such as a dimension D5, a dimension D6, a dimension D7, and/or a dimension D8, among other examples. The dimension D5 may correspond to a cross-sectional thickness (e.g., a z-direction thickness) of the main portion 510a of the modulator heater structure 506. Moreover, the dimension D5 may correspond to a cross-sectional thickness (e.g., a z-direction thickness) of the heater ring 514. In some implementations, the dimension D5 is included in a range of approximately 80 nanometers to approximately 240 nanometers. Values less than approximately 80 nanometers for the dimension D5 may result in non-uniform heating of the optical modulator structure 502 because of process variations in forming the heater ring 514. Values greater than approximately 240 nanometers for the dimension D5 may result in insufficient electrical resistance in the heater ring 514 and, therefore, the heater ring 514 may not be able to sufficiently heat the optical modulator structure 502. However, ranges for the dimension D5 other than approximately 80 nanometers to approximately 240 nanometers may be used and are within the scope of the present disclosure.

The dimension D6 may correspond to a cross-sectional thickness (e.g., a z-direction thickness) of an extension portion 510b of the modulator heater structure 506. In some implementations, the dimension D6 is included in a range of approximately 200 nanometers to approximately 300 nanometers to achieve a sufficiently low electrical resistance in the heater pads 518a and/or 518b, which enables a high energy efficiency to be achieved for the modulator heater structure 506. However, ranges for the dimension D6 other than approximately 200 nanometers to approximately 300 nanometers may be used and are within the scope of the present disclosure.

The dimension D7 may correspond to a cross-sectional thickness (e.g., a z-direction thickness) of the heater pads 518a and/or 518b of the modulator heater structure 506. Thus, the dimension D7 may correspond to a combined thickness of the main portion 510a (e.g., the dimension D5) and an extension portion 510b (e.g., the dimension D6) of the modulator heater structure 506. In some implementations, the dimension D7 is included in a range of approximately 280 nanometers to approximately 540 nanometers to achieve a sufficiently low electrical resistance in the heater pads 518a and/or 518b, which enables a high energy efficiency to be achieved for the modulator heater structure 506. However, ranges for the dimension D7 other than approximately 280 nanometers to approximately 540 nanometers may be used and are within the scope of the present disclosure.

The dimension D8 may correspond to a cross-sectional width (e.g., a y-direction width) of the extension section 512 of the modulator heater structure 506. In some implementations, the dimension D8 is included in a range of approximately 5 microns to approximately 10 microns. Values less than approximately 5 microns for the dimension D8 may result in the extension portion(s) 510b being unable to withstand the processing temperatures needed for forming the extension portion(s) 510b. Values greater than approximately 10 microns for the dimension D8 may result in insufficient electrical resistance in the heater ring 514 and, therefore, the heater ring 514 may not be able to sufficiently heat the optical modulator structure 502. However, ranges for the dimension D8 other than approximately 5 microns to approximately 10 microns may be used and are within the scope of the present disclosure.

Accordingly, the semiconductor device 500 may include a first dielectric layer (e.g., the dielectric layer 522), an etch stop layer (e.g., the etch stop layer 526) over the first dielectric layer, a second dielectric layer (e.g., the dielectric layer 524) over the etch stop layer, an optical modulator structure 502 in the first dielectric layer, and a modulator heater structure 506 above the optical modulator structure 502 and included in the second dielectric layer. The modulator heater structure 506 may include a heater ring 514 directly over the optical modulator structure 502, a heater pad (e.g., a heater pad 518a and/or 518b) coupled with the heater ring 514, and a contact region (e.g., a contact region 520a and/or 520b) coupled with the heater pad. The semiconductor device 500 may further include a BEOL interconnect layer 508 on and coupled with the contact region of the modulator heater structure 506, and a BEOL extension layer (e.g., an extension layer 510) on and coupled with the heater pad.

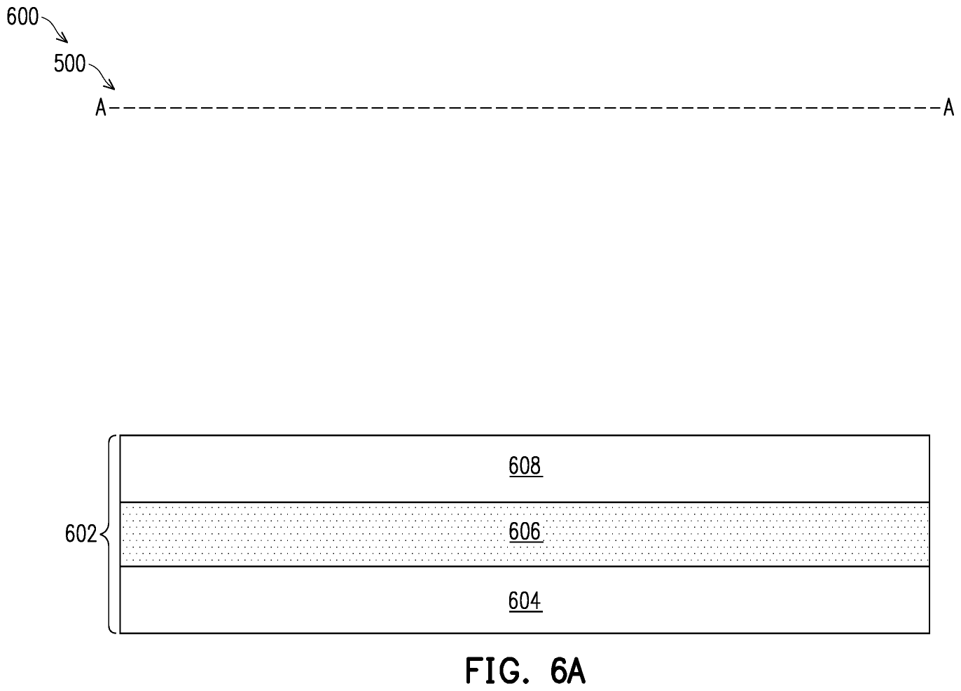

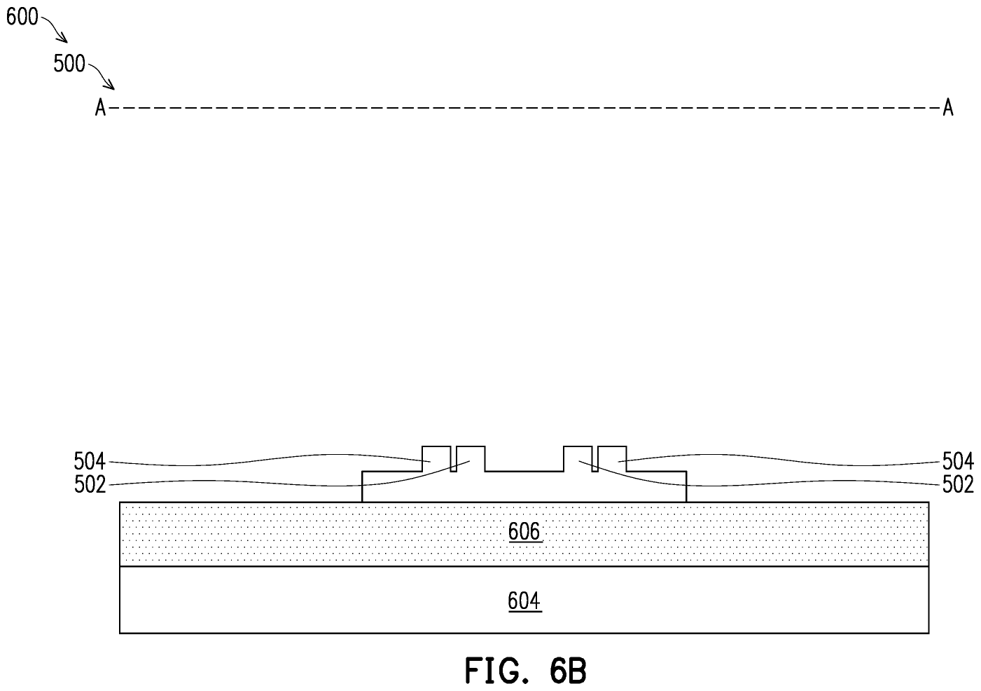

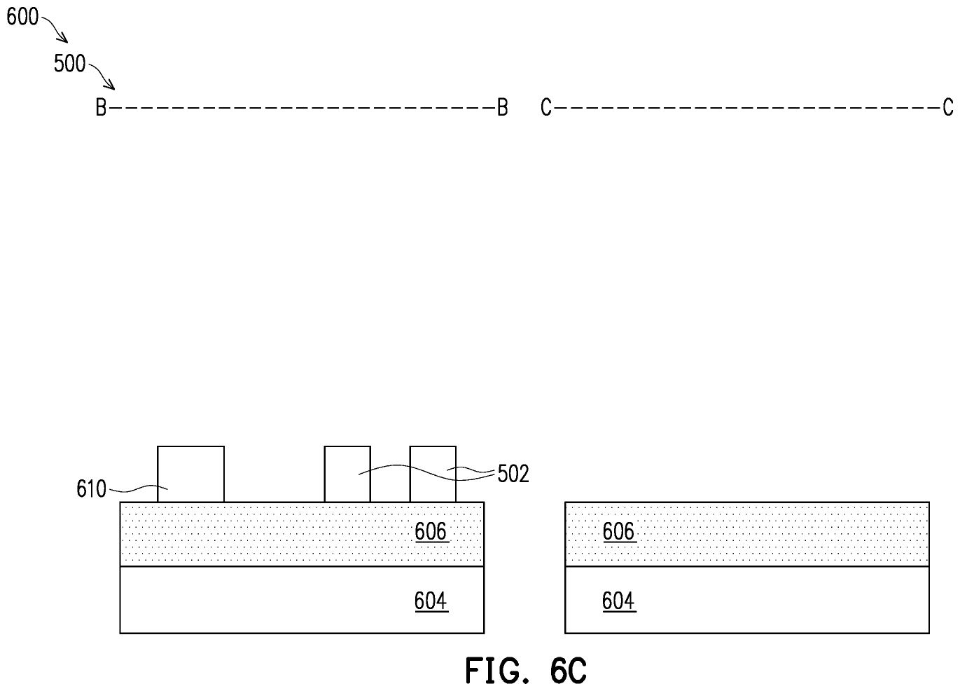

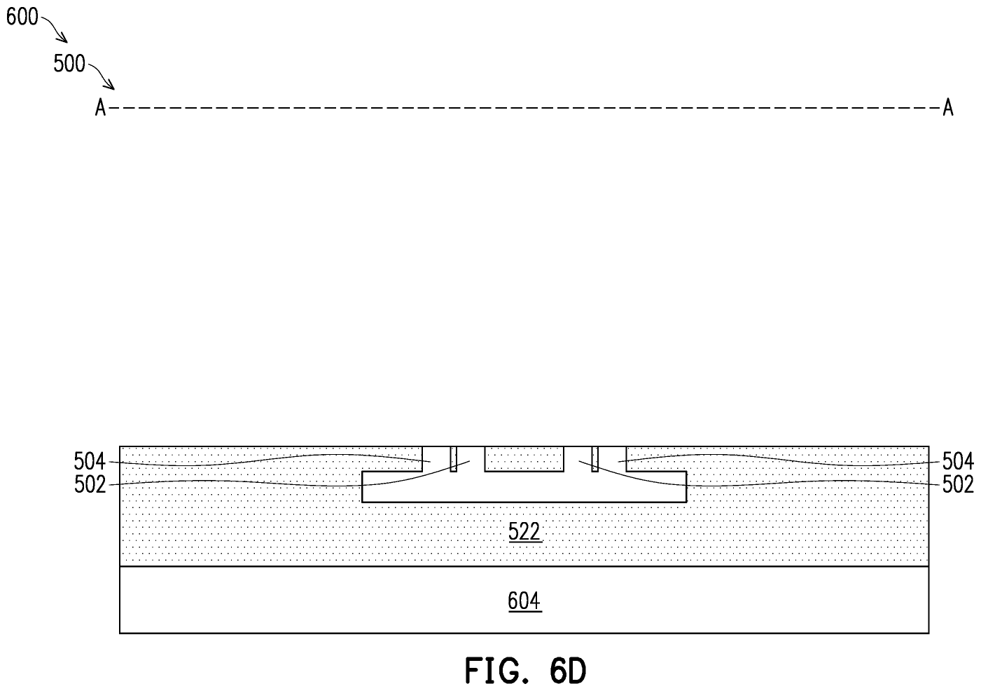

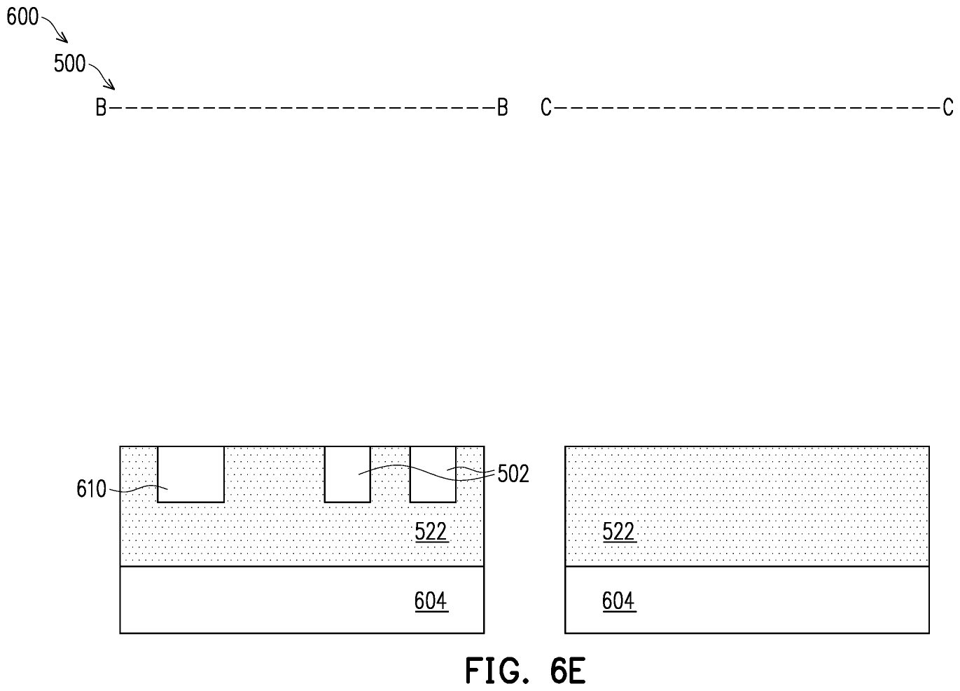

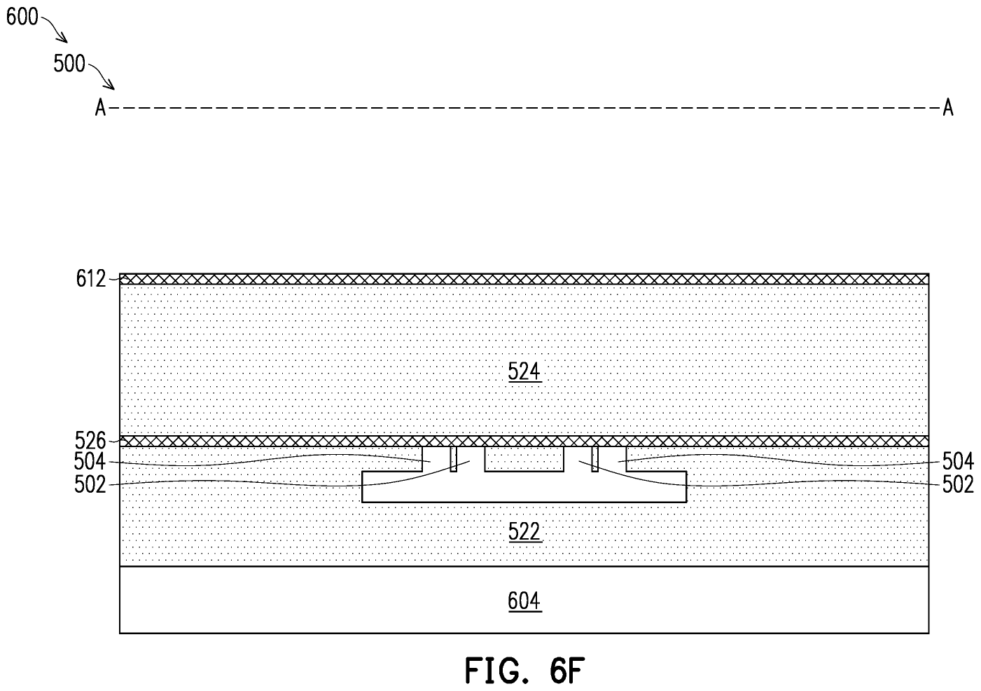

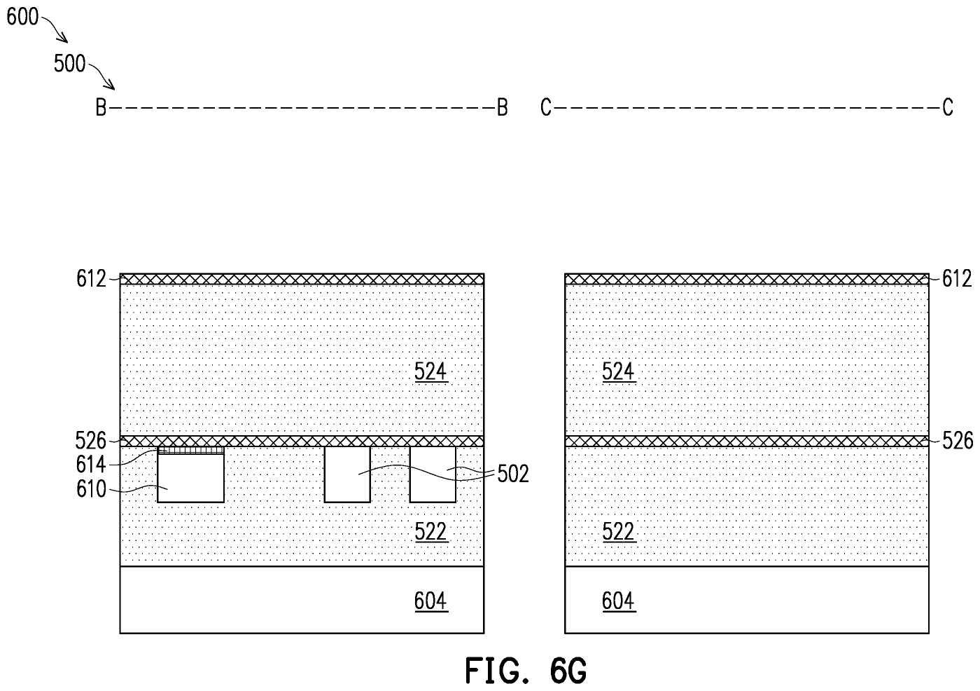

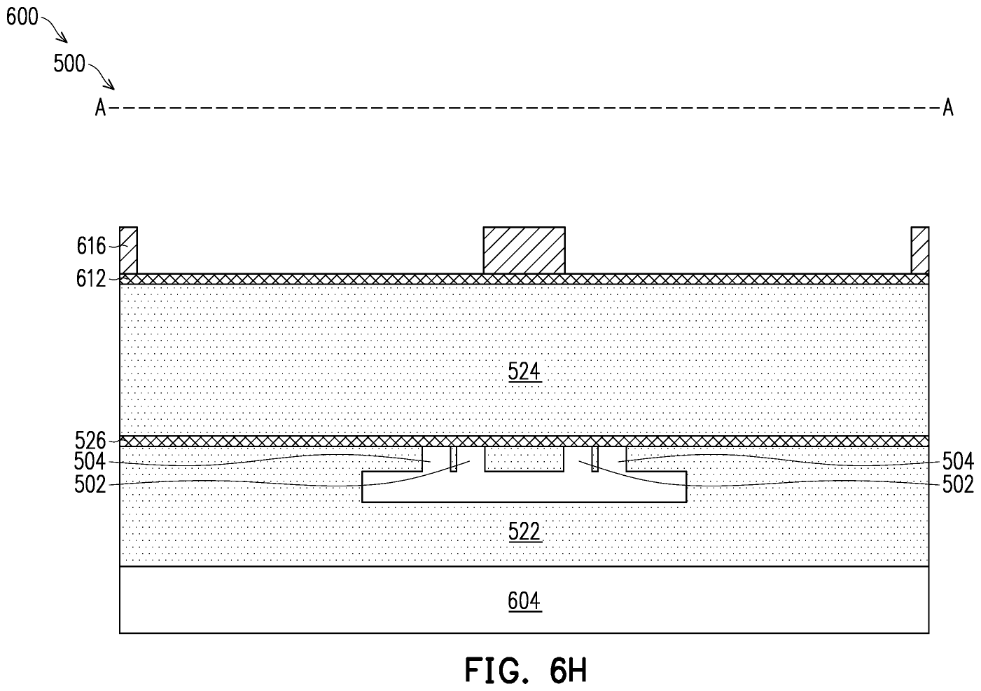

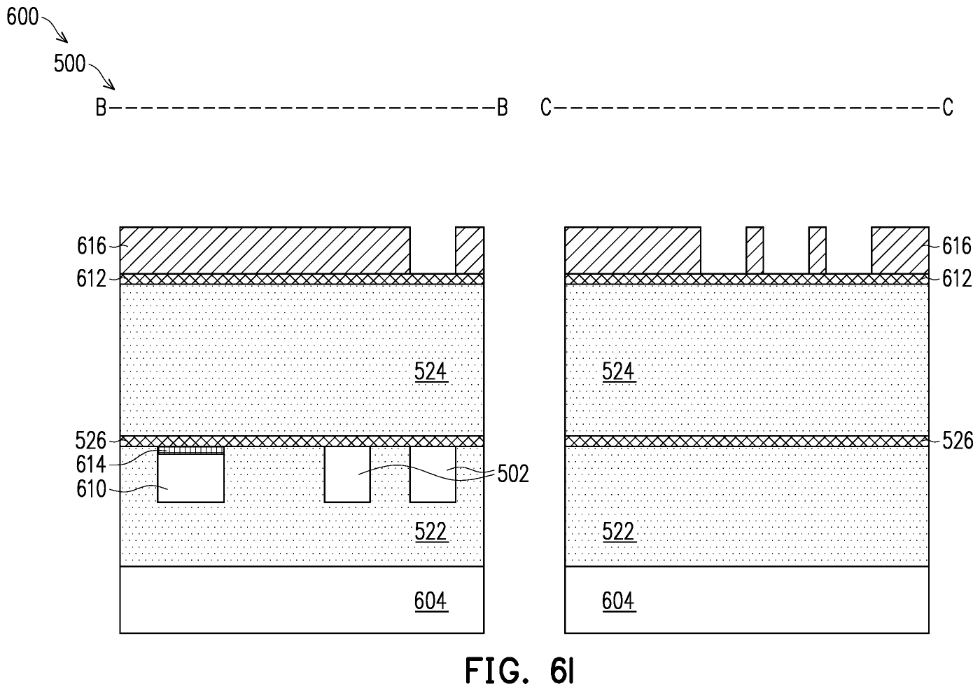

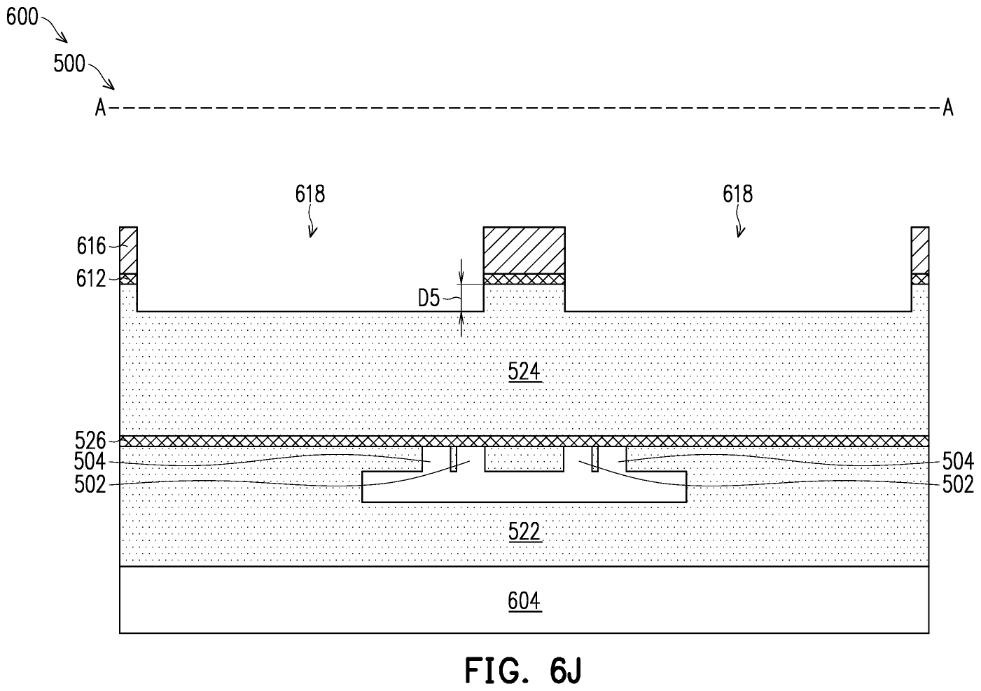

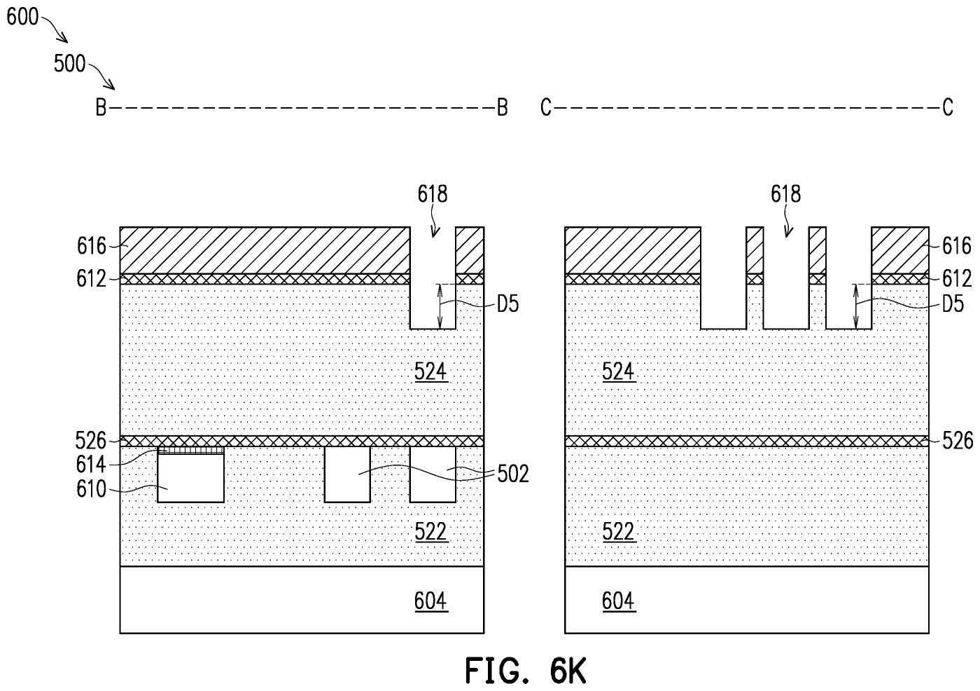

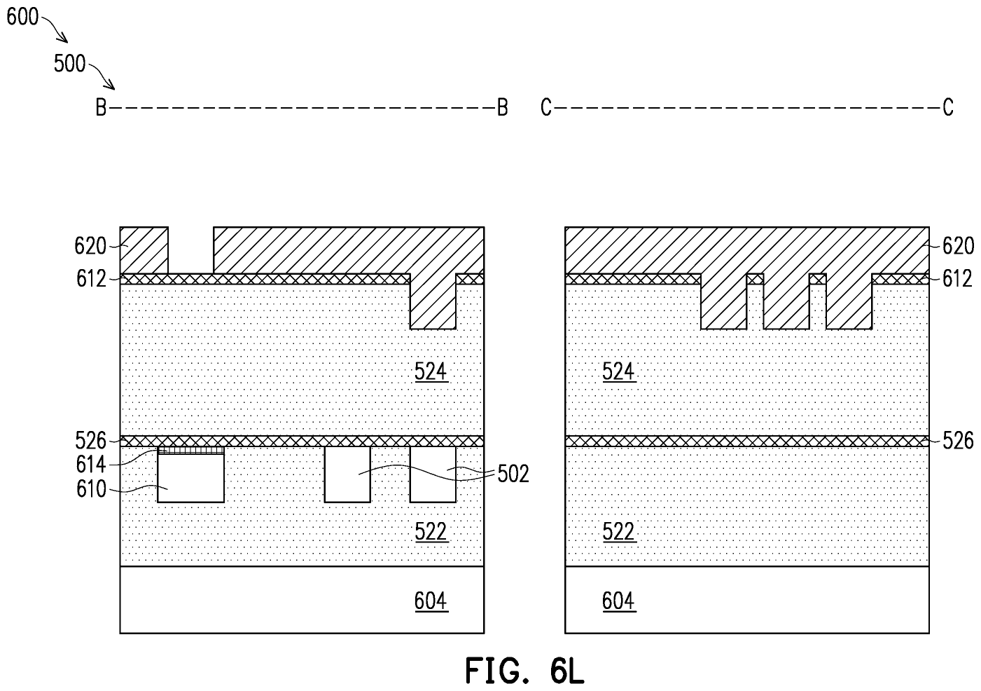

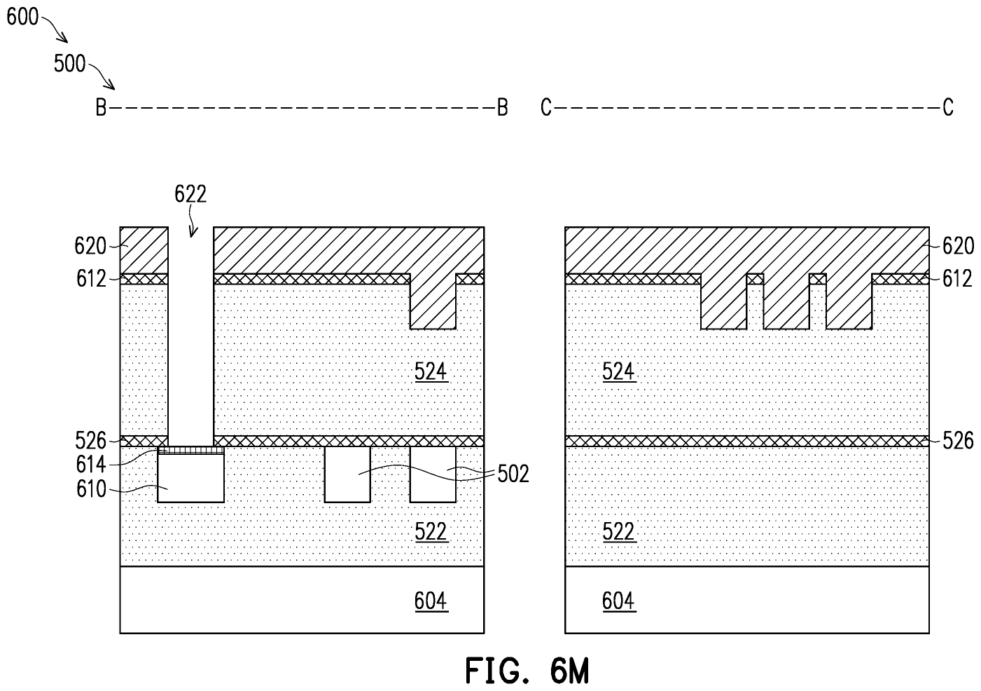

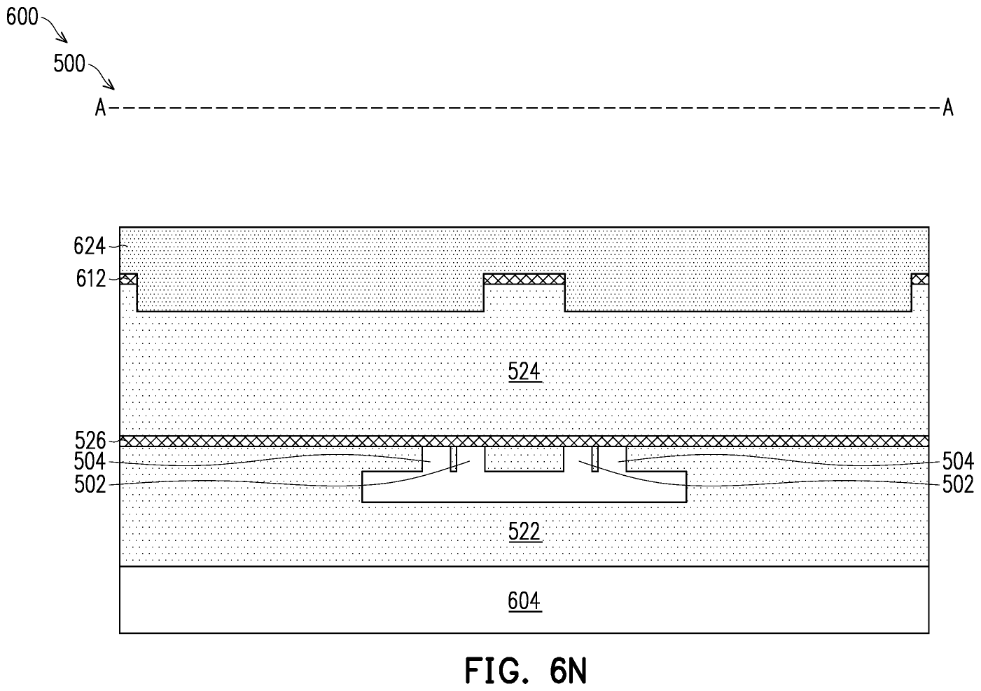

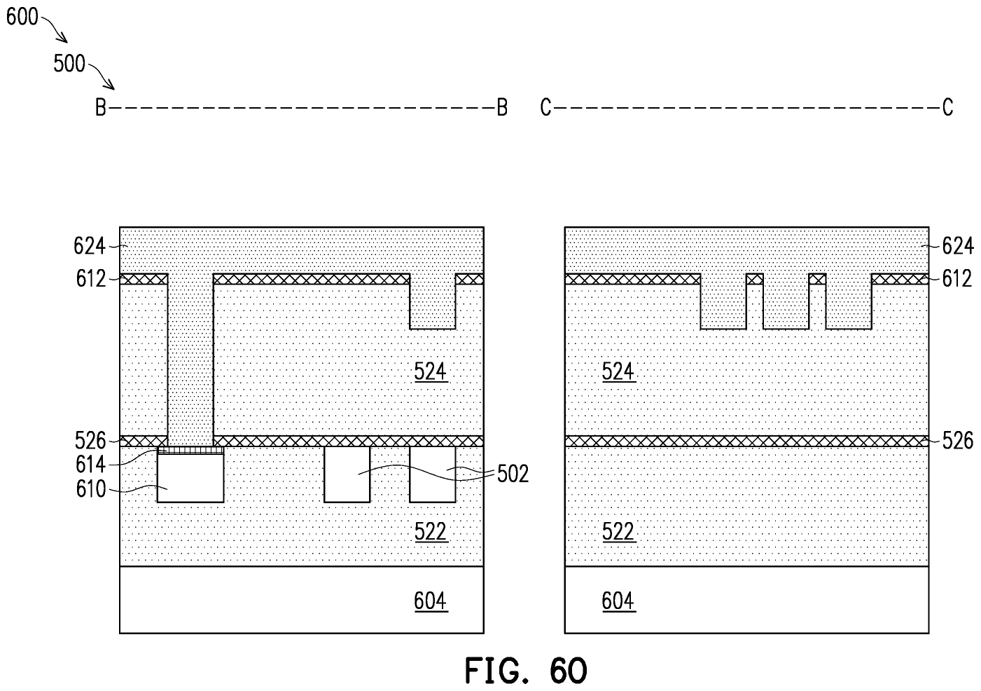

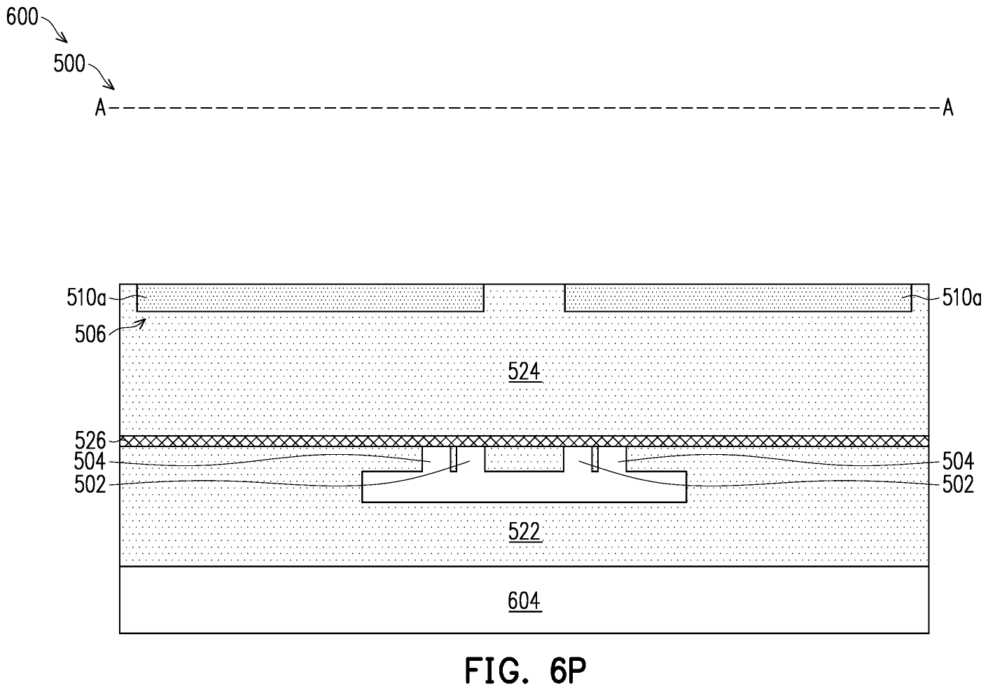

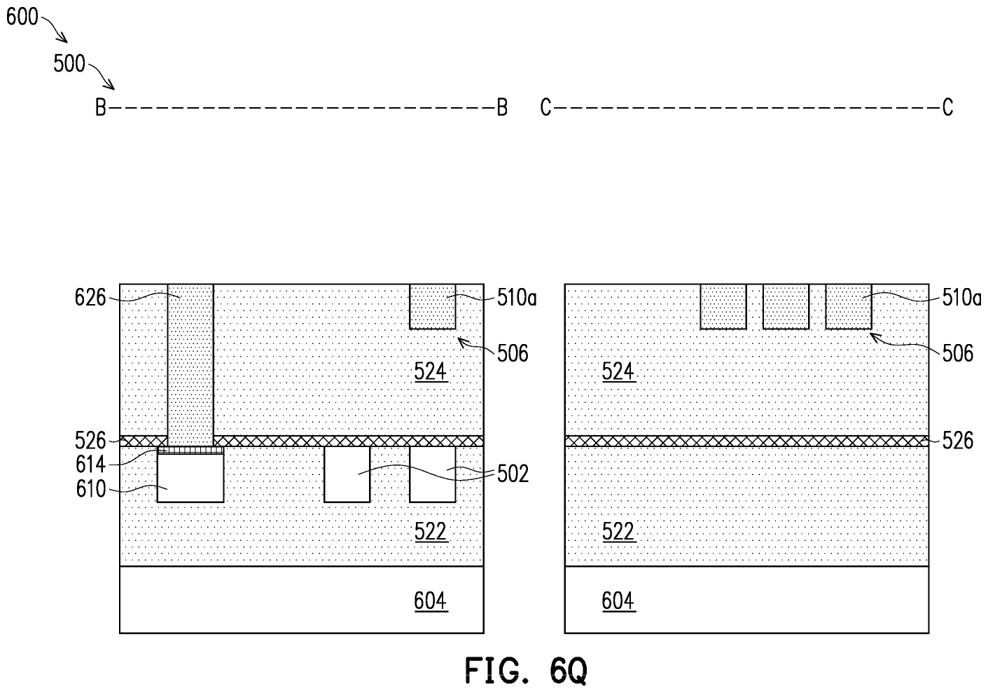

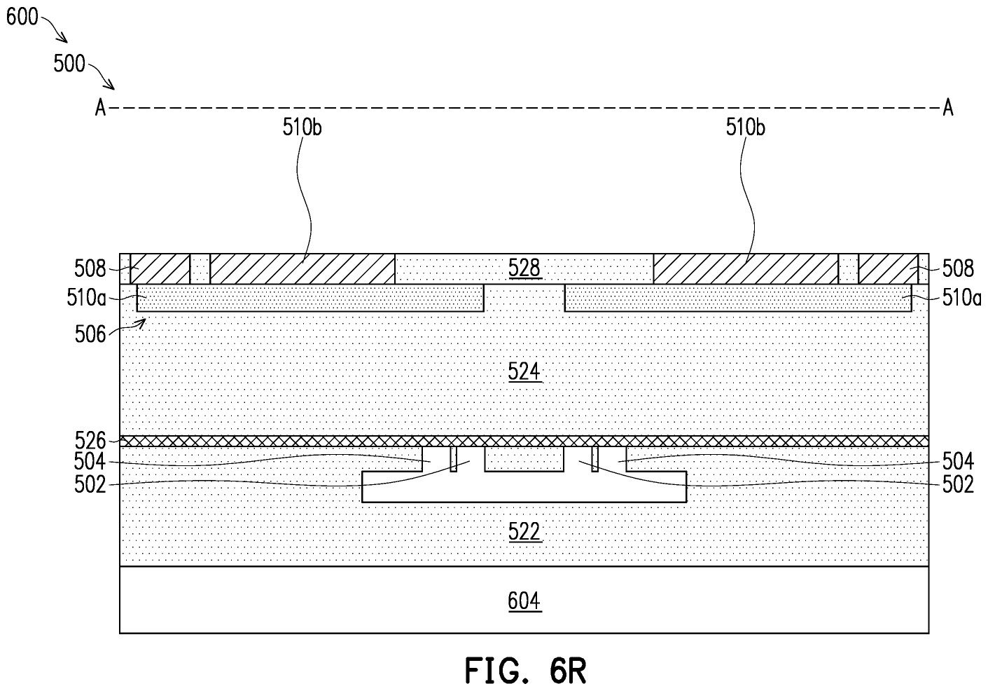

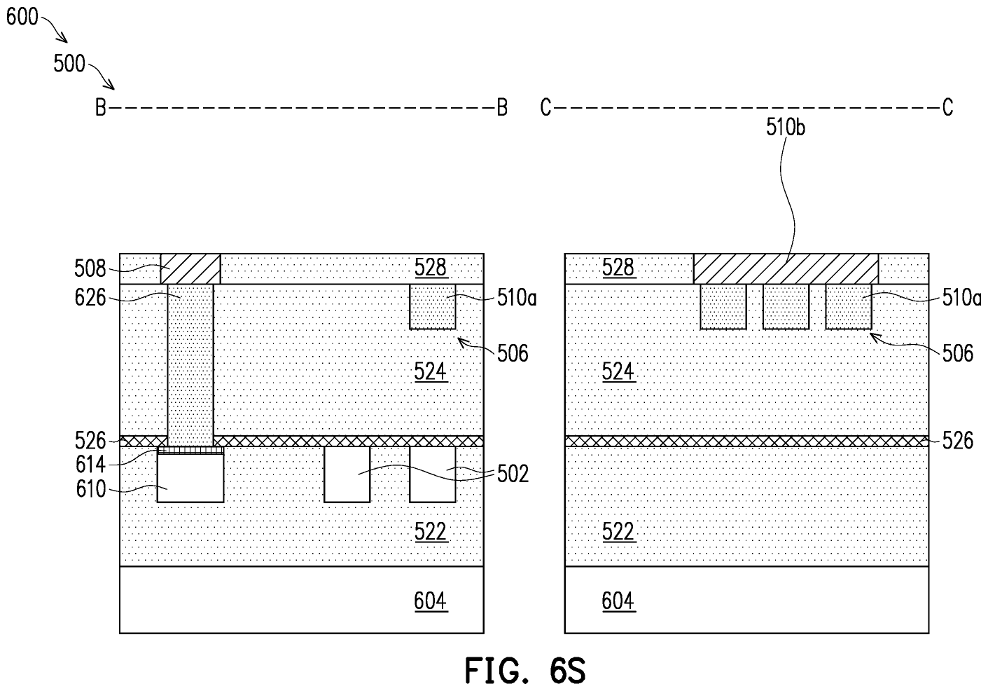

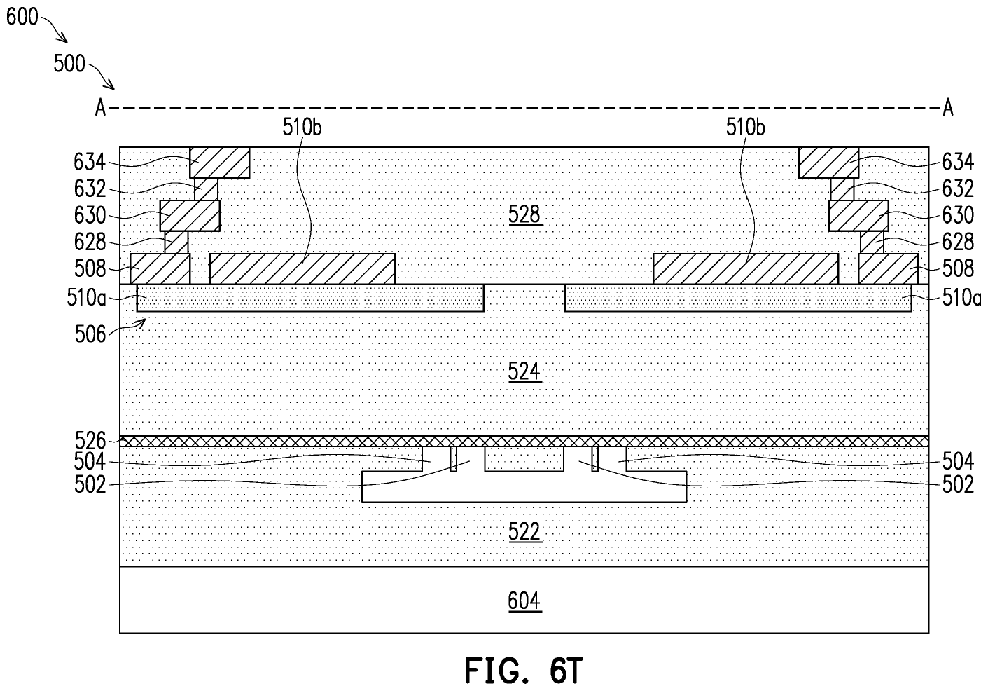

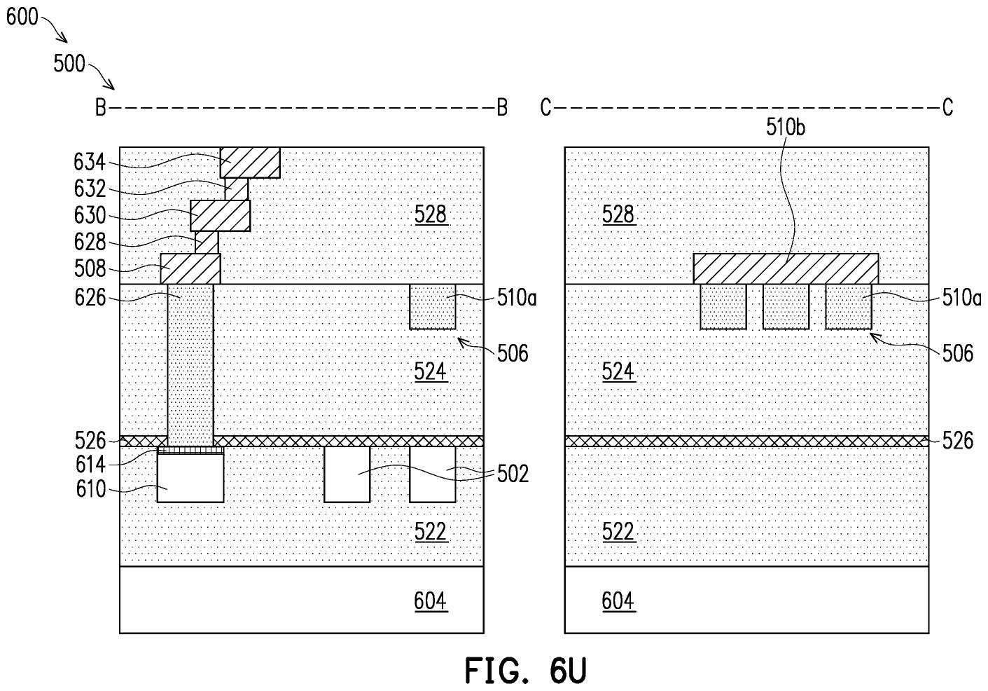

Various cross-sectional lines are illustrated in FIG. 5 and referenced in connection with one or more of FIGS. 6A-6U. The cross-sectional line A-A is in the second direction (e.g., the y-direction) in the semiconductor device 500 and extends along the modulator heater structure 506. A cross-sectional line B-B is in the first direction (e.g., the x-direction) in the semiconductor device 500 and extends across the heater ring 514 of the modulator heater structure 506. A cross-sectional line C-C is in the first direction (e.g., the x-direction) in the semiconductor device 500 and extends across a heater pad 518a of the modulator heater structure 506.

As indicated above, FIG. 5 is provided as an example. Other examples may differ from what is described with regard to FIG. 5.

FIGS. 6A-6U are diagrams of an example implementation 600 of forming the semiconductor device 500 (or a portion thereof) described herein. In some implementations, one or more of the semiconductor processing operations described in connection with the example implementation 600 may be performed using one or more of the semiconductor processing tools 102-114 and/or by the wafer/die transport tool 116. In some implementations, one or more of the semiconductor processing operations described in connection with the example implementation 600 may be performed using another semiconductor processing tool.

Turning to FIG. 6A, a substrate 602 may be provided. The substrate 402 may include an SOI substrate that includes a semiconductor substrate 604 (e.g., a silicon (Si) substrate and/or another type of semiconductor substrate), a dielectric layer 606 (e.g., a BOX layer and/or another type of insulator layer) over and/or on the semiconductor substrate 604, and a semiconductor layer 608 (e.g., a silicon (Si) layer and/or another type of semiconductor layer) over and/or on the dielectric layer 606. Alternatively, the semiconductor substrate 604 may be provided as a semiconductor wafer, and the deposition tool 102 may be used to form the dielectric layer 606 over and/or on the semiconductor substrate 604, and another deposition tool 102 may be used to form the semiconductor layer 608 over and/or on the dielectric layer 606. A deposition tool 102 may be used to form the dielectric layer 606 using a CVD technique, a PVD technique, an oxidation technique (e.g., a thermal oxidation technique), and/or another type of deposition technique. A deposition tool 102 may be used to form the semiconductor layer 608 using a CVD technique, a PVD technique, an epitaxy technique, and/or another type of deposition technique.

As shown in FIGS. 6B and 6C, the optical modulator structure 502 and the waveguide structure 504 may be formed in the semiconductor layer 608. As shown in FIG. 6C, a contact structure 610 may also be formed in the semiconductor layer 608. The contact structure 610 may be formed adjacent to the optical modulator structure 502 and may be used to provide an electrical input to the optical modulator structure 502 for generating a modulated optical signal.

In some implementations, a pattern in a masking layer (e.g., a hard mask layer, a photoresist layer) is used to etch the semiconductor layer 608 to form the optical modulator structure 502, the waveguide structure 504, and/or the contact structure 610. The deposition tool 102 may be used to form the masking layer on the semiconductor layer 608 (e.g., using a CVD technique, a PVD technique, and/or another type of deposition technique). An exposure tool 104 and an etch tool 108 may be used to remove portions of the masking layer to form the pattern in the masking layer. An etch tool 108 may then be used to perform an etch operation to etch the semiconductor layer 608 based on the pattern in the masking layer to form the optical modulator structure 502, the waveguide structure 504, and/or the contact structure 610. In some implementations, the etch operation includes a plasma etch operation, a wet chemical etch operation, and/or another type of etch operation. In some implementations, a photoresist removal tool is used to remove the remaining portions of the masking layer (e.g., using a chemical stripper, plasma ashing, and/or another technique). In some implementations, a planarization tool 110 is used to remove the remaining portions of the masking layer using a CMP technique and/or another type of planarization technique.

As shown in FIGS. 6D and 6E, dielectric material may be deposited over the dielectric layer 606 to encapsulate the optical modulator structure 502, the waveguide structure 504, and/or the contact structure 610 in the dielectric layer 522 of the semiconductor device 500. The deposition tool 102 may be used to deposit the dielectric material using a CVD technique, a PVD technique, an oxidation technique (e.g., a thermal oxidation technique), and/or another type of deposition technique. In some implementations, one or more additional semiconductor processing operations may be performed to deposit the additional material of the dielectric layer 522. For example, the deposition tool 102 may be used to perform an STI liner oxidation operation and/or an HDP deposition operation to deposit the dielectric material of the dielectric layer 522. As another example, a planarization tool 110 may be used to perform a CMP operation and/or another type of planarization operation to planarize the dielectric layer 522 after the dielectric material. The CMP operation may result in top surfaces of the optical modulator structure 502, the waveguide structure 504, and/or the contact structure 610 being exposed through the dielectric layer 522.

In some implementations, one or more portions of the optical modulator structure 502 may be subsequently doped with one or more types of dopants to form one or more doped regions in the optical modulator structure 502. For example, the ion implantation tool 114 may be used (e.g., using an ion implantation technique and/or another type of doping technique) to implant one or more portions of the optical modulator structure 502 with p-type ions to form one or more p-type regions in the optical modulator structure 502. As another example, the ion implantation tool 114 may be used (e.g., using an ion implantation technique and/or another type of doping technique) to implant one or more portions of the optical modulator structure 502 with n-type ions to form one or more n-type regions in the optical modulator structure 502.

As shown in FIGS. 6F and 6G, one or more additional layers may be formed over and/or on the dielectric layer 522 after formation of the optical modulator structure 502, after formation of the waveguide structure 504, and/or after formation of the contact structure 610. For example, the etch stop layer 526 may be formed over and/or on the dielectric layer 522. As another example, the dielectric layer 524 may be formed over and/or on the etch stop layer 526. As another example, an etch stop layer 612 may be formed over and/or on the dielectric layer 524.

A deposition tool 102 may be used to deposit the etch stop layer 526, the dielectric layer 524, and/or the etch stop layer 612 in one or more PVD operations, one or more ALD operations, one or more CVD operations, one or more epitaxy operations, one or more oxidation operations, one or more deposition operations of another type described in connection with FIG. 1, and/or one or more deposition operations of another type. In some implementations, a planarization tool 110 planarizes the etch stop layer 526, the dielectric layer 524, and/or the etch stop layer 612 after a deposition tool 102 deposits the etch stop layer 526, the dielectric layer 524, and/or the etch stop layer 612.

As further shown in FIG. 6G, in some implementations, a silicide layer 614 may be formed over and/or on the top surface of the contact structure 610 prior to formation of the one or more additional layers. The silicide layer 614 may include a metal silicide layer that is included to achieve a relatively low contact resistance for the contact structure 610 and/or to reduce the likelihood of native oxides forming on the top surface of the contact structure 610. A deposition tool 102 may be used to deposit the silicide layer 614 using a CVD technique, a PVD technique, an ALD technique, and/or another deposition technique. In some implementations, a deposition tool 102 may be used to perform a pre-clean operation to remove oxides (e.g., native oxides) from the top surface of the contact structure 610 prior to formation of the silicide layer 614.

As shown in FIGS. 6H and 61, a masking layer 616 may be formed over and/or on the etch stop layer 612. The masking layer 616 may include a hard mask layer, a photoresist layer, and/or another type of masking layer. A deposition tool 102 may be used to deposit the masking layer 616 in one or more PVD operations, one or more ALD operations, one or more CVD operations, one or more epitaxy operations, one or more oxidation operations, one or more deposition operations of another type described in connection with FIG. 1, and/or one or more deposition operations of another type. A pattern may then be formed in the masking layer 616. In some implementations, the pattern may be formed by using an etch tool 108 to etch the masking layer 616 to remove portions of the masking layer 616.

As shown in FIGS. 6J and 6K, the masking layer 616 may be used to etch through the etch stop layer 612 and into a portion of the dielectric layer 524 to form a recess 618 in the dielectric layer 524. The recess 618 may be formed to a depth corresponding to the dimension D5. An etch tool 108 may be used to perform an etch operation to etch the etch stop layer 612 and the dielectric layer 524 to form the recess 618. In some implementations, the etch operation includes a plasma etch operation, a wet chemical etch operation, and/or another type of etch operation. In some implementations, a photoresist removal tool is used to remove the remaining portions of the masking layer 616 (e.g., using a chemical stripper, plasma ashing, and/or another technique). In some implementations, a planarization tool 110 is used to remove the remaining portions of the masking layer 616 using a CMP technique and/or another type of planarization technique.

As shown in FIG. 6L, a masking layer 620 may be formed over and/or on the etch stop layer 612 and in the recess 618 such that the recess 618 is covered by the masking layer 620. The masking layer 620 may include a hard mask layer, a photoresist layer, and/or another type of masking layer. A deposition tool 102 may be used to deposit the masking layer 620 in one or more PVD operations, one or more ALD operations, one or more CVD operations, one or more epitaxy operations, one or more oxidation operations, one or more deposition operations of another type described in connection with FIG. 1, and/or one or more deposition operations of another type. A pattern may then be formed in the masking layer 620. In some implementations, the pattern may be formed by using an etch tool 108 to etch the masking layer 620 to remove portions of the masking layer 620 over the contact structure 610.

As shown in FIG. 6M, the etch stop layer 612, the dielectric layer 524, and the etch stop layer 526 may be etched using the pattern in the masking layer 620 to form a recess 622 over the contact structure 610. The silicide layer 614 on the top surface of the contact structure 610 may be exposed through the recess. An etch tool 108 may be used to perform an etch operation to etch the etch stop layer 612, the dielectric layer 524, and the etch stop layer 526 to form the recess 622. In some implementations, the etch operation includes a plasma etch operation, a wet chemical etch operation, and/or another type of etch operation. In some implementations, a photoresist removal tool is used to remove the remaining portions of the masking layer 620 (e.g., using a chemical stripper, plasma ashing, and/or another technique). In some implementations, a planarization tool 110 is used to remove the remaining portions of the masking layer 620 using a CMP technique and/or another type of planarization technique.

As shown in FIGS. 6N and 6O, an electrically conductive material layer 624 may be formed in the recess 618 and in the recess 622. The electrically conductive material layer 624 may land on the silicide layer 614 that is on the top surface of the contact structure 610. The electrically conductive material layer 624 may include tungsten (W), titanium (Ti), copper (Cu), ruthenium (Ru), cobalt (Co), and/or another electrically conductive material. A deposition tool 102 and/or a plating tool 112 may be used to deposit the electrically conductive material layer 624 in one or more PVD operations, one or more ALD operations, one or more CVD operations, one or more electroplating operations, one or more deposition operations of another type described in connection with FIG. 1, and/or one or more deposition operations of another type. In some implementations, a seed layer is first deposited, and the electrically conductive material layer 624 is deposited on the seed layer.

As shown in FIGS. 6P and 6Q, material may be removed from the electrically conductive material layer 624. The remaining portions of the electrically conductive material layer 624 may correspond to the main portion 510a of the modulator heater structure 506 (which may be formed in the recess 618) and an interconnect structure 626 (which may be formed in the recess 622 over the contact structure 610). A planarization tool 110 may be used to planarize the electrically conductive material layer 624 to remove the material from the electrically conductive material layer 624.

As shown in FIGS. 6R and 6S, a portion of the BEOL region of the semiconductor device 500 may be formed over the FEOL region of the semiconductor device 500. For example, the dielectric layer 528 may be formed over and/or on the dielectric layer 524 and over and/or on the main portion 510a of the modulator heater structure 506. BEOL interconnect layers 508 may be formed in the dielectric layer 528. BEOL interconnect layers 508 may be formed over and/or on the modulator heater structure 506, and over and/or on the interconnect structure 626, among other examples. The BEOL interconnect layers 508 may be approximately co-planar and may be referred to as a metal-1 (M1) layer of the BEOL region.

Additionally, the extension portion(s) 510b of the modulator heater structure 506 may be formed in the dielectric layer 528 and on the modulator heater structure 506 (e.g., on the heater pads 518a and/or 518b of the modulator heater structure 506) as part of the BEOL region formation process. The extension portion(s) 510b may be formed in the same set of one or more M1 layer semiconductor processing operations as the BEOL interconnect layers 508. The extension portion(s) 510b may be formed to a thickness corresponding to the dimension D6 such that the overall thickness of the heater pads 518a and/or 518b corresponds to the dimension D7.

A deposition tool 102 may be used to deposit the dielectric layer 528 in one or more PVD operations, one or more ALD operations, one or more CVD operations, one or more epitaxy operations, one or more oxidation operations, one or more deposition operations of another type described in connection with FIG. 1, and/or one or more deposition operations of another type. A deposition tool 102 and/or a plating tool 112 may be used to deposit the BEOL interconnect layers 508 and/or the extension portion(s) 510b in one or more PVD operations, one or more ALD operations, one or more CVD operations, one or more electroplating operations, one or more deposition operations of another type described in connection with FIG. 1, and/or one or more deposition operations of another type. In some implementations, a seed layer is first deposited, and the BEOL interconnect layers 508 and/or the extension portion(s) 510b are deposited on the seed layer. A planarization tool 110 may be used to perform a CMP operation and/or another type of planarization operation to planarize the BEOL interconnect layers 508 and/or the extension portion(s) 510b.

As shown in FIGS. 6T and 6U, additional metallization layers of the BEOL region may be formed over and/or on the BEOL interconnect layers 508. For example, a BEOL interconnect layer 628 (e.g., a via-1 layer) may be formed over and/or on the BEOL interconnect layers 508. As another example, a BEOL interconnect layer 630 (e.g., a metal-2 or M2 layer) may be formed over and/or on the BEOL interconnect layers 628. As another example, a BEOL interconnect layer 632 (e.g., a via-2 layer) may be formed over and/or on the BEOL interconnect layers 630. As another example, a BEOL interconnect layer 634 (e.g., a metal-3 or M3 layer) may be formed over and/or on the BEOL interconnect layers 632.

A deposition tool 102 and/or a plating tool 112 may be used to deposit the BEOL interconnect layers 628-634 in one or more PVD operations, one or more ALD operations, one or more CVD operations, one or more electroplating operations, one or more deposition operations of another type described in connection with FIG. 1, and/or one or more deposition operations of another type. In some implementations, a seed layer is first deposited, and the BEOL interconnect layers 628-634 are deposited on the seed layer. A planarization tool 110 may be used to perform a CMP operation and/or another type of planarization operation to planarize the BEOL interconnect layers 628-634.

As indicated above, FIGS. 6A-6U are provided as examples. Other examples may differ from what is described with regard to FIGS. 6A-6U.

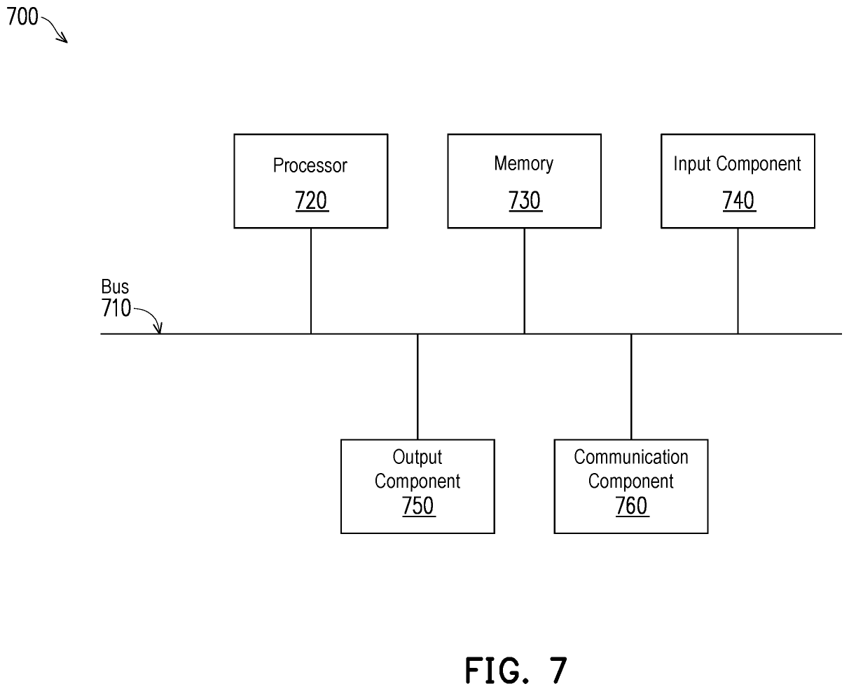

FIG. 7 is a diagram of example components of a device 700 described herein. In some implementations, one or more of the semiconductor processing tools 102-114 and/or the wafer/die transport tool 116 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

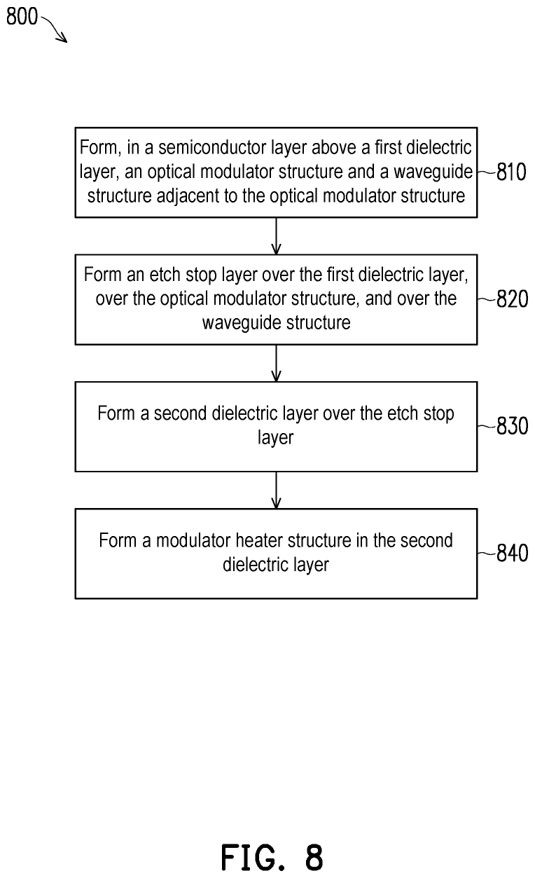

FIG. 8 is a flowchart of an example process 800 associated with forming a semiconductor photonics device described herein. In some implementations, one or more process blocks of FIG. 8 are performed using one or more semiconductor processing tools (e.g., one or more of the semiconductor processing tools 102-114). Additionally, or alternatively, one or more process blocks of FIG. 8 may be performed using one or more components of device 700, such as processor 720, memory 730, input component 740, output component 750, and/or communication component 760.

As shown in FIG. 8, process 800 may include forming, in a semiconductor layer above a first dielectric layer, an optical modulator structure and a waveguide structure adjacent to the optical modulator structure (block 810). For example, one or more of the semiconductor processing tools 102-114 may be used to form, in a semiconductor layer (e.g., a semiconductor layer 408, a semiconductor layer 608) above a first dielectric layer (e.g., a dielectric layer 406, a dielectric layer 606), an optical modulator structure (e.g., an optical modulator structure 202, an optical modulator structure 502) and a waveguide structure (e.g., a waveguide structure 204, a waveguide structure 504) adjacent to the optical modulator structure, as described herein.

As further shown in FIG. 8, process 800 may include forming an etch stop layer over the first dielectric layer, over the optical modulator structure, and over the waveguide structure (block 820). For example, one or more of the semiconductor processing tools 102-114 may be used to form an etch stop layer (e.g., an etch stop layer 226, an etch stop layer 526) over the first dielectric layer, over the optical modulator structure, and over the waveguide structure, as described herein.

As further shown in FIG. 8, process 800 may include forming a second dielectric layer over the etch stop layer (block 830). For example, one or more of the semiconductor processing tools 102-114 may be used to form a second dielectric layer (e.g., a dielectric layer 224, a dielectric layer 524) over the etch stop layer, as described herein.

As further shown in FIG. 8, process 800 may include forming a modulator heater structure in the second dielectric layer (block 840). For example, one or more of the semiconductor processing tools 102-114 may be used to form a modulator heater structure (e.g., a modulator heater structure 206, a modulator heater structure 506) in the second dielectric layer, as described herein. In some implementations, a heater ring (e.g., a heater ring 214, a heater ring 514) of the modulator heater structure is formed over the optical modulator structure. In some implementations, a heater pad (e.g., a heater pad 218a, a heater pad 218b, a heater pad 518a, a heater pad 518b) of the modulator heater structure, coupled with the heater ring, extends laterally outward from the heater ring. In some implementations, a thickness (e.g., a dimension D3, a dimension D7) of the heater pad is greater relative to a thickness of the heater ring (e.g., a dimension D1, a dimension D5).

Process 800 may include additional implementations, such as any single implementation or any combination of implementations described below and/or in connection with one or more other processes described elsewhere herein.

In a first implementation, forming the modulator heater structure includes etching, using a first masking layer (e.g., a masking layer 416) in a first etch operation, a recess (e.g., a recess 418) in the second dielectric layer to a first depth (e.g., a dimension D1) in the second dielectric layer, etching, using a second masking layer (e.g., a masking layer 420) over a first portion (e.g., a portion 418a) of the recess in a second etch operation after the first etch operation, the second dielectric layer to increase the first depth in a second portion (e.g., a portion 418a) of the recess to a second depth (e.g., a dimension D3), where the first portion remains at the first depth as a result of the second masking layer being over the first portion, depositing an electrically conductive material layer (e.g., an electrically conductive material layer 426) in the recess after the second etch operation, and planarizing the electrically conductive material layer to form the modulator heater structure.

In a second implementation, alone or in combination with the first implementation, the first portion of the recess is over the waveguide structure and the optical modulator structure.

In a third implementation, alone or in combination with one or more of the first and second implementations, the heater ring is formed in first portion of the recess, and the heater pad is formed in the second portion of the recess.

In a fourth implementation, alone or in combination with one or more of the first through third implementations, forming the modulator heater structure includes etching, using a masking layer (e.g., a masking layer 616) in an etch operation, a recess (e.g., a recess 618) in the second dielectric layer, depositing an electrically conductive material layer (e.g., an electrically conductive material layer 624) in the recess after the etch operation, planarizing the electrically conductive material layer to form the modulator heater structure, and forming an extension layer (e.g., an extension portion 510b) of the heater pad on the modulator heater structure.

In a fifth implementation, alone or in combination with one or more of the first through fourth implementations, process 800 includes forming a third dielectric layer (e.g., a dielectric layer 528) over the second dielectric layer, where forming the extension layer of the heater pad includes forming the extension layer of the heater pad in the third dielectric layer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a modulator heater structure may include a plurality of regions having different thicknesses. For example, a heater ring of the modulator heater structure may have a first thickness. A heater pad of the modulator heater structure, that is configured to provide an electrical current to the heater ring, may have a second thickness that is greater than the first thickness. The lesser thickness of the heater ring of the modulator heater structure provides high electrical resistance in the heater ring, which enables the heater ring to quickly and efficiently generate heat that may be provided to stabilize the operating temperature of an optical modulator structure. The greater thickness of the heater pad provides low electrical resistance in the second region, which enables the electrical current to be efficiently provided through the heater pad to the heater ring with reduced heat dissipation in the hear pad due to the lower electrical current dissipation in the heater pad. This enables the modulator heater structure to operate more efficiently, and to consume less electrical current to provide a similar amount of heat to the optical modulator relative to other modulator heater structure configurations.

As described in greater detail above, some implementations described herein provide a semiconductor device. The semiconductor device includes a first dielectric layer. The semiconductor device includes an etch stop layer over the first dielectric layer. The semiconductor device includes a second dielectric layer over the etch stop layer. The semiconductor device includes an optical modulator structure in the first dielectric layer. The semiconductor device includes a modulator heater structure, above the optical modulator structure, included in the second dielectric layer, where the modulator heater structure comprises: a heater ring directly over the optical modulator structure a heater pad coupled with the heater ring, where a thickness of the heater pad is greater than a thickness of the heater ring.

As described in greater detail above, some implementations described herein provide a semiconductor device. The semiconductor device includes a first dielectric layer. The semiconductor device includes an etch stop layer over the first dielectric layer. The semiconductor device includes a second dielectric layer over the etch stop layer. The semiconductor device includes an optical modulator structure in the first dielectric layer. The semiconductor device includes a modulator heater structure, above the optical modulator structure, included in the second dielectric layer, where the modulator heater structure comprises: a heater ring directly over the optical modulator structure a heater pad coupled with the heater ring a contact region coupled with the heater pad. The semiconductor device includes a BEOL interconnect layer on and coupled with the contact region of the modulator heater structure. The semiconductor device includes a BEOL extension layer on and coupled with the heater pad.

As described in greater detail above, some implementations described herein provide a method. The method includes forming, in a semiconductor layer above a first dielectric layer, an optical modulator structure and a waveguide structure adjacent to the optical modulator structure. The method includes forming an etch stop layer over the first dielectric layer, over the optical modulator structure, and over the waveguide structure. The method includes forming a second dielectric layer over the etch stop layer. The method includes forming a modulator heater structure in the second dielectric layer, where a heater ring of the modulator heater structure is formed over the optical modulator structure, where a heater pad of the modulator heater structure, coupled with the heater ring, extends laterally outward from the heater ring, and where a thickness of the heater pad is greater relative to a thickness of the heater ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first dielectric layer;
an etch stop layer over the first dielectric layer;
a second dielectric layer over the etch stop layer;
an optical modulator structure in the first dielectric layer; and
a modulator heater structure, above the optical modulator structure, included in the second dielectric layer,
wherein the modulator heater structure comprises:
a heater ring directly over the optical modulator structure; and
a heater pad coupled with the heater ring,
wherein a thickness of the heater pad is greater than a thickness of the heater ring.

2. The semiconductor device of claim 1, wherein the modulator heater structure further comprises:
a first heater portion that extends between a contact region of the modulator heater structure and a connection region, of the modulator heater structure, that couples the heater ring and the heater pad; and
a second heater portion that extends between the contact region and the heater ring.

3. The semiconductor device of claim 2, wherein the first heater portion includes an overhang section that extends laterally outward from an end of the second heater portion.

4. The semiconductor device of claim 3, further comprising:
a waveguide structure in the first dielectric layer and adjacent to the optical modulator structure,
wherein the overhang section is located over the optical modulator structure and the waveguide structure.

5. The semiconductor device of claim 1, wherein a bottom surface of the heater pad is located closer to the etch stop layer than a bottom surface of the heater ring.

6. A semiconductor device, comprising:
a first dielectric layer;
an etch stop layer over the first dielectric layer;
a second dielectric layer over the etch stop layer;
an optical modulator structure in the first dielectric layer;
a modulator heater structure, above the optical modulator structure, included in the second dielectric layer,
wherein the modulator heater structure comprises:
a heater ring directly over the optical modulator structure;
a heater pad coupled with the heater ring; and
a contact region coupled with the heater pad;
a back end of line (BEOL) interconnect layer on and coupled with the contact region of the modulator heater structure; and
a BEOL extension layer on and coupled with the heater pad.

7. The semiconductor device of claim 6, wherein a thickness of a combination of the heater pad and the BEOL extension layer is greater relative to a thickness of the heater ring.

8. The semiconductor device of claim 6, wherein the BEOL extension layer and the modulator heater structure include different material compositions.

9. The semiconductor device of claim 6, wherein a material interface is located between the BEOL extension layer and the heater pad of the modulator heater structure.

10. The semiconductor device of claim 6, wherein the modulator heater structure includes an extension section that extends laterally outward from an end of the BEOL extension layer.

11. The semiconductor device of claim 10, further comprising:
a waveguide structure in the first dielectric layer and adjacent to the optical modulator structure,
wherein the extension section is located over the optical modulator structure and the waveguide structure.

12. The semiconductor device of claim 6, wherein a top surface of the BEOL extension layer and a top surface of the BEOL interconnect layer are approximately co-planar in the semiconductor device.

13. The semiconductor device of claim 6, wherein the BEOL extension layer is electrically coupled with the BEOL interconnect layer through the modulator heater structure.

14. The semiconductor device of claim 6, wherein the BEOL interconnect layer and the BEOL extension layer are included in a third dielectric layer that is over the second dielectric layer.

15. A method, comprising:
forming, in a semiconductor layer above a first dielectric layer, an optical modulator structure and a waveguide structure adjacent to the optical modulator structure;
forming an etch stop layer over first dielectric layer, over the optical modulator structure, and over the waveguide structure;
forming a second dielectric layer over the etch stop layer; and
forming a modulator heater structure in the second dielectric layer,
wherein a heater ring of the modulator heater structure is formed over the optical modulator structure,
wherein a heater pad of the modulator heater structure, coupled with the heater ring, extends laterally outward from the heater ring, and
wherein a thickness of the heater pad is greater relative to a thickness of the heater ring.

16. The method of claim 15, wherein forming the modulator heater structure comprises:
etching, using a first masking layer in a first etch operation, a recess in the second dielectric layer to a first depth in the second dielectric layer;
etching, using a second masking layer over a first portion of the recess in a second etch operation after the first etch operation, the second dielectric layer to increase the first depth in a second portion of the recess to a second depth,
wherein the first portion remains at the first depth as a result of the second masking layer being over the first portion;
depositing an electrically conductive material layer in the recess after the second etch operation; and
planarizing the electrically conductive material layer to form the modulator heater structure.

17. The method of claim 16, wherein the first portion of the recess is over the waveguide structure and the optical modulator structure.

18. The method of claim 16, wherein the heater ring is formed in first portion of the recess; and
wherein the heater pad is formed in the second portion of the recess.

19. The method of claim 15, wherein forming the modulator heater structure comprises:
etching, using a masking layer in an etch operation, a recess in the second dielectric layer;
depositing an electrically conductive material layer in the recess after the etch operation;
planarizing the electrically conductive material layer to form the modulator heater structure; and
forming an extension layer of the heater pad on the modulator heater structure.

20. The method of claim 19, further comprising:
forming a third dielectric layer over the second dielectric layer,
wherein forming the extension layer of the heater pad comprises:
forming the extension layer of the heater pad in the third dielectric layer.
